(19) United States
(12) Patent Application Publication
(10) Pub. No.: US 2025/0081773 A1
(43) Pub. Date: Mar. 6, 2025

(54) DISPLAY DEVICE AND WEARABLE DEVICE

(71) Applicant: Samsung Display Co., LTD., Yongin-si (KR)

(72) Inventors: Yong Hee LEE, Yongin-si (KR); Kyung Bae KIM, Yongin-si (KR); Kyeong Min PARK, Yongin-si (KR)

(21) Appl. No.: 18/672,852

(22) Filed: May 23, 2024

(30) Foreign Application Priority Data
Aug. 31, 2023 (KR) 10-2023-0115475

(51) Int. Cl. H10K 59/131; G02B 27/01; H10K 59/122; H10K 59/35

(52) U.S. Cl. CPC H10K 59/131; G02B 27/0172; H10K 59/122; H10K 59/352; H10K 59/353

(57) ABSTRACT

A display device includes: a substrate including a non-display area and a display area; sub-pixels in the display area; and metal lines traversing the non-display area and the display area in a first direction. Each of the metal lines extends in the first direction to not overlap with emission areas of the sub-pixels, and includes metal patterns protruding in a direction crossing the first direction between the emission areas.

### CROSS-REFERENCE TO RELATED APPLICATION

The present application claims priority to and the benefit of Korean patent application No. 10-2023-0115475, filed on Aug. 31, 2023, in the Korean Intellectual Property Office, the entire disclosure of which is incorporated by reference herein.

### BACKGROUND

### 1. Field

Aspects of embodiments of the present disclosure generally relate to a display device and a wearable device.

### 2. Description of the Related Art

With the development of information technologies, the importance of a display device that is a connection medium between a user and information increases. Accordingly, various display devices, such as a liquid crystal display device, an organic light emitting display device, and an inorganic light emitting display device, are increasingly used.

A display device displays an image using pixels. In order to implement Augmented Reality (AR), Virtual Reality (VR), and/or Mixed Reality (MR), a larger number of pixels that are disposed on a small display surface in the display device may be desired.

The above information disclosed in this Background section is for enhancement of understanding of the background of the present disclosure, and therefore, it may contain information that does not constitute prior art.

### SUMMARY

As a distance between pixels is narrowed, a leakage current through a common layer of adjacent pixels may be caused.

One or more embodiments of the present disclosure are directed to a display device and a wearable display device that may prevent or reduce a leakage current through a common layer between adjacent pixels.

According to one or more embodiments of the present disclosure, a display device includes: a substrate including a non-display area and a display area; sub-pixels in the display area; and metal lines traversing the non-display area and the display area in a first direction. Each of the metal lines extends in the first direction to not overlap with emission areas of the sub-pixels, and includes metal patterns protruding in a direction crossing the first direction between the emission areas.

In an embodiment, each of the metal patterns may have a ring shape.

In an embodiment, each of the metal lines may be located on a pixel defining layer, and the pixel defining layer may define the emission areas of the sub-pixels in the display area.

In an embodiment, display device may further include: a first metal pad in the non-display area; and a second metal pad in the non-display area, the second metal pad being located in the first direction from the first metal pad. The metal lines may connect the first metal pad and the second metal pad to each other.

In an embodiment, shapes of the metal lines may be the same as each other.

In an embodiment, the sub-pixels may include a first sub-pixel, a second sub-pixel, and a third sub-pixel located along the first direction. The metal lines may include a first metal line, the first metal line including: a first metal pattern protruding in a second direction crossing the first direction between a first emission area of the first sub-pixel and a second emission area of the second sub-pixel; and a second metal pattern protruding in the second direction between the second emission area and a third emission area of the third sub-pixel.

In an embodiment, a length of each of the first metal pattern and the second metal pattern in the second direction may be longer than a length of each of the first emission area, the second emission area, and the third emission area in the second direction.

In an embodiment, the first metal line may further include: a first line portion located in an opposite direction of the second direction from the first emission area, the first line portion being connected to the first metal pattern; a second line portion located in the opposite direction of the second direction from the second emission area, the second line portion connecting the first metal pattern and the second metal pattern to each other; and a third line portion located in the opposite direction of the second direction from the third emission area, the third line portion being connected to the second metal pattern.

In an embodiment, the sub-pixels may further include a fourth sub-pixel, a fifth sub-pixel, and a sixth sub-pixel located along the first direction. The metal lines may further include a second metal line traversing between the first emission area and a fourth emission area of the fourth sub-pixel, between the second emission area and a fifth emission area of the fifth sub-pixel, and between the third emission area and a sixth emission area of the sixth sub-pixel. A first metal line and the second metal line may be spaced from each other.

In an embodiment, the metal lines may further include a dummy metal line located in the second direction from outermost sub-pixels in the second direction from among the sub-pixels.

In an embodiment, the metal lines may include: a first group of metal lines including metal patterns protruding in a second direction crossing the first direction; and a second group of metal lines including metal patterns protruding in an opposite direction of the second direction. The first group of metal lines and the second group of metal lines may be alternately located along the second direction.

In an embodiment, the first group of metal lines and the second group of metal lines may have shapes that are symmetrical to each other with respect to the second direction.

In an embodiment, the sub-pixels may include a first sub-pixel and a second sub-pixel located along the first direction. The metal lines may include a first metal line sequentially including along the first direction: a first metal pattern protruding in a second direction crossing the first direction; a second metal pattern protruding in an opposite direction of the second direction; a third metal pattern protruding in the second direction; a fourth metal pattern protruding in the opposite direction of the second direction; and a fifth metal pattern protruding in the second direction. A first emission area of the first sub-pixel may be located in the second direction from the second metal pattern, and a second emission area of the second sub-pixel may be located in the second direction from the fourth metal pattern.

In an embodiment, the first metal line may further include: a first line portion connecting the first metal pattern and the second metal pattern to each other; a second line portion connecting the second metal pattern and the third metal pattern to each other; a third line portion connecting the third metal pattern and the fourth metal pattern to each other; and a fourth line portion connecting the fourth metal pattern and the fifth metal pattern to each other. The first line portion and the third line portion may be parallel to each other; the second line portion and the fourth line portion may be parallel to each other; and the first line portion and the second line portion may not be parallel to each other.

In an embodiment, the sub-pixels may further include a third sub-pixel. The metal lines may further include a second metal line sequentially including along the first direction: a sixth metal pattern protruding in the opposite direction of the second direction; a seventh metal pattern protruding in the second direction; an eighth metal pattern protruding in the opposite direction of the second direction; a ninth metal pattern protruding in the second direction; and a tenth metal pattern protruding in the opposite direction of the second direction. The first emission area may be located in the opposite direction of the second direction from the seventh metal pattern, the second emission area may be located in the opposite direction of the second direction from the ninth metal pattern, and a third emission area of the third sub-pixel may be located in the second direction from the eighth metal pattern.

In an embodiment, the third metal pattern and the eighth metal pattern may face each other between the first emission area and the second emission area.

In an embodiment, the metal lines may further include a third metal line sequentially including along the first direction: an eleventh metal pattern protruding in the opposite direction of the second direction; a twelfth metal pattern protruding in the second direction; and a thirteenth metal pattern protruding in the opposite direction of the second direction. The third emission area may be located in the opposite direction of the second direction from the twelfth metal pattern, the eleventh metal pattern and the seventh metal pattern may face each other in the second direction, and the thirteenth metal pattern and the ninth metal pattern may face each other in the second direction.

In an embodiment, the metal lines may include: a first metal line sequentially including along the first direction: a first metal pattern protruding in a second direction crossing the first direction; a second metal pattern protruding in the second direction; and a third metal pattern protruding in the second direction; and a second metal line sequentially including along the first direction: a fourth metal pattern protruding in an opposite direction of the second direction; a fifth metal pattern protruding in the opposite direction of the second direction; and a sixth metal pattern protruding in the opposite direction of the second direction. The first metal line may further include: a first line portion connecting the first metal pattern and the second metal pattern to each other; and a second line portion connecting the second metal pattern and the third metal pattern to each other. The second metal line may further include: a third line portion connecting the fourth metal pattern and the fifth metal pattern to each other; and a fourth line portion connecting the fifth metal pattern and the sixth metal pattern to each other. Positions of the first line portion and the second line portion may be the same as each other with respect to the second direction, and positions of the third line portion and the fourth line portion may be different from each other with respect to the second direction.

In an embodiment, the sub-pixels may include: a first sub-pixel including a first emission area; a second sub-pixel located in the first direction from the first sub-pixel, and including a second emission area; and a third sub-pixel located in the second direction from the first sub-pixel, and including a third emission area. A length of the second emission area in the second direction may be longer than a length of each of the first emission area and the third emission area in the second direction, the first emission area may be located between the first line portion and the third line portion, the second emission area may be located between the second line portion and the fourth line portion, and the third emission area may be located in the second direction from the third line portion.

In an embodiment, the second metal pattern and the fifth metal pattern may face each other between the first emission area and the second emission area.

According to one or more embodiments of the present disclosure, a wearable device includes: a first display panel; and a second display panel. Each of the first display panel and the second display panel includes: a substrate including a non-display area and a display area; sub-pixels in the display area; and metal lines traversing the non-display area and the display area in a first direction. Each of the metal lines extends in the first direction to not overlap with emission areas of the sub-pixels, and includes metal patterns protruding in a direction crossing the first direction between the emission areas.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of a display device according to one or more embodiments.

FIG. 2 is a block diagram illustrating one of sub-pixels shown in FIG. 1 according to one or more embodiments.

FIG. 3 is a plan view illustrating a display panel shown in FIG. 1 according to one or more embodiments.

FIG. 4 is an exploded perspective view illustrating a portion of the display panel shown in FIG. 3.

FIG. 5 is a plan view illustrating pixels shown in FIG. 4 according to one or more embodiments.

FIG. 6 is a sectional view taken along the line I-I′ shown in FIG. 5.

FIG. 7 is a sectional view illustrating a light emitting structure included in one of first to third light emitting elements shown in FIG. 6 according to one or more embodiments.

FIG. 8 is a sectional view illustrating the light emitting structure included in one of the first to third light emitting elements shown in FIG. 6 according to one or more embodiments.

FIG. 9 is a sectional view taken along the line I-I′ shown in FIG. 5 according to one or more embodiments.

FIG. 10 is a view illustrating a differently configured metal line that is applied to the pixels shown in FIG. 5 according to one or more embodiments.

FIG. 11 is a view illustrating a metal line that is applied to another kind of pixels according to one or more embodiments.

FIG. 12 is a view illustrating a metal line that is applied to another kind of pixels according to one or more embodiments.

FIG. 13 is a view illustrating a connection portion of a metal pad and metal lines.

FIG. 14 is a diagram illustrating a display system according to one or more embodiments.

FIG. 15 is a perspective view illustrating an application example of the display system shown in FIG. 14.

FIG. 16 is a view illustrating a head mounted display device shown in FIG. 15 that is worn by a user.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

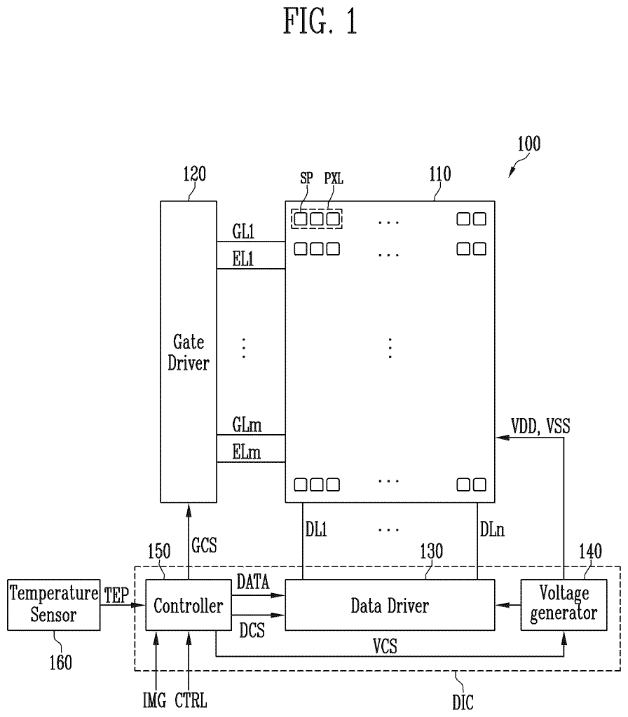

FIG. 1 is a block diagram of a display device according to one or more embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm, where m is a natural number. The sub-pixels SP may be connected to the data driver 130 through first to nth data lines DL1 to DLn, where n is a natural number.

Each of the sub-pixels SP may include at least one light emitting element to generate light. Accordingly, each of the sub-pixels SP may generate light of a desired color (e.g., a specific or predetermined color), such as red, green, blue, cyan, magenta, or yellow. Two or more sub-pixels from among the sub-pixels SP may constitute one pixel PXL. For example, three sub-pixels may constitute one pixel PXL as shown in FIG. 1.

The gate driver 130 may be connected to the sub-pixels SP arranged in a row direction through the first to mth gate lines GL1 to GLm. The gate driver 120 may output gate signals to the first to mth gate lines GL1 to GLm in response to a gate control signal GCS. In one or more embodiments, the gate control signal GCS may include a start signal indicating a start of each frame, a horizontal synchronization signal for outputting gate signals in synchronization with timings at which data signals are applied, and the like.

In one or more embodiments, first to mth emission control lines EL1 to ELm connected to the sub-pixels SP in the row direction may be further provided. The gate driver 120 may include an emission control driver to control the first to mth emission control lines EL1 to ELm, and the emission control driver may operate under the control of the controller 150.

The gate driver 120 may be disposed at one side of the display panel 110. However, the present disclosure is not limited thereto. For example, the gate driver 120 may be divided into two or more drivers that are physically and/or logically divided, and these drivers may be disposed at one side of the display panel 110 and another side of the display panel 110 that is opposite to the one side. As such, in some embodiments, the gate driver 120 may be disposed in various suitable forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In one or more embodiments, the data control signal DCS may include a source start pulse, a source shift clock, a source output enable signal, and the like.

The data driver 130 may apply data signals having grayscale voltages (e.g., grayscale level or gray level voltages) corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLn. Therefore, corresponding sub-pixels SP may generate light corresponding to the data signals. Accordingly, an image may be displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages, and may provide the generated voltages to various components of the display device 100. For example, the voltage generator 140 may receive an input voltage from the outside of the display device 100, adjust the received voltage, and regulate the adjusted voltage, thereby generating a plurality of voltages.

The voltage generator 140 may generate a first power voltage VDD and a second power voltage VSS. The generated first and second power voltages VDD and VSS may be provided to the sub-pixels SP. The first power voltage VDD may have a relatively high voltage level, and the second power voltage VSS may have a voltage level lower than the voltage level of the first power voltage VDD. However, the present disclosure is not limited thereto, and in some embodiments, the first power voltage VDD and/or the second power voltage VSS may be provided by an external device of the display device 100.

In addition, the voltage generator 140 may generate various suitable voltages. For example, the voltage generator 140 may generate an initialization voltage that is applied to the sub-pixels SP. For example, in a sensing operation for sensing electrical characteristics of transistors and/or light emitting elements of the sub-pixels SP, a reference voltage (e.g., a predetermined reference voltage) may be applied to the first to nth data lines DL1 to DLn, and the voltage generator 140 may generate the reference voltage.

The controller 150 may control the overall operations of the display device 100. The controller 150 may receive, from the outside, input image data IMG and a control signal CTRL for controlling a display thereof. The controller 150 may provide the gate control signal GCS, the data control signal DCS, and the voltage control signal VCS in response to the received control signal CTRL.

The controller 150 may convert the input image data IMG to be suitable for the display device 100 or the display panel 110, thereby outputting the image data DATA. In one or more embodiments, the controller 150 may align the input image data IMG to be suitable for the sub-pixels SP in units of rows, thereby outputting the image data DATA.

Two or more components from among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components that are functionally divided in the driver integrated circuit DIC (e.g., in one driver integrated circuit DIC). However, the present disclosure is not limited thereto, and in some embodiments, at least one of the data driver 130, the voltage generator 140, and/or the controller 150 may be provided as a component that is distinguished from the driver integrated circuit DIC.

The display device 100 may include at least one temperature sensor 160. The temperature sensor 160 may be configured to sense a temperature at the periphery thereof, and generate temperature data TEP indicating the sensed temperature. In one or more embodiments, the temperature sensor 160 may be disposed adjacent to the display panel 110 and/or the driver integrated circuit DIC.

The controller 150 may control various operations of the display device 100 in response to the temperature data TEP. In one or more embodiments, the controller 150 may adjust a luminance of an image output from the display panel 110 in response to the temperature data TEP. For example, the controller 150 may control various components, such as the data driver 130 and/or the voltage generator 140, to adjust the data signals and/or the first and second power voltages VDD and VSS according to the temperature data TEP.

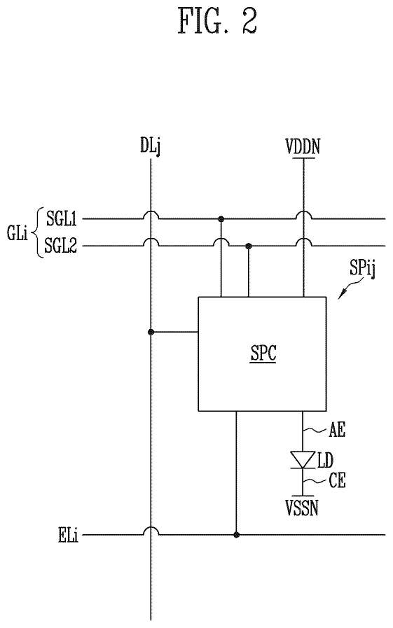

FIG. 2 is a block diagram illustrating one of the sub-pixels shown in FIG. 1 according to one or more embodiments. In FIG. 2, a sub-pixel SPij arranged at (e.g., in or on) an ith row (where i is an integer greater than or equal to 1 and smaller than or equal to m) and a jth column (where j is an integer greater than or equal to 1 and smaller than or equal to n) from among the sub-pixels SP shown in FIG. 1 is illustrated for convenience. Each of the sub-pixels SP shown in FIG. 1 may have the same or substantially the same structure as that of the sub-pixel SPij shown in FIG. 2, and thus, redundant description may not be repeated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node for transferring the first power voltage VDD shown in FIG. 1. The second power voltage node VSSN may be a node for transferring the second power voltage VSS shown in FIG. 1.

An anode electrode AE of the light emitting element LD may be connected to the first power voltage node VDDN through the sub-pixel circuit SPC. For example, the anode electrode AE of the light emitting element LD may be connected to the first power voltage node VDDN through one or more transistors included in the sub-pixel circuit SPC. A cathode electrode CE of the light emitting element LD may be connected to the second power voltage node VSSN.

The sub-pixel circuit SPC may be connected to an ith gate line GLi from among the first to mth gate lines GL1 to GLm shown in FIG. 1, an ith emission control line ELi from among the first to mth emission control lines EL1 to Elm shown in FIG. 1, and a jth data line DLj from among the first to nth data lines DL1 to DLn shown in FIG. 1. The sub-pixel circuit SPC may control the light emitting element LD according to signals received through the above-described signal lines.

The sub-pixel circuit SPC may operate in response to a gate signal received through the ith gate line GLi. The ith gate line GLi may include one or more sub-gate lines. In one or more embodiments, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding two or more sub-gate lines.

The sub-pixel circuit SPC may operate in response to an emission control signal received through the ith emission control line ELi. In one or more embodiments, the ith emission control line ELi may include one or more sub-emission control lines. When the ith emission control line ELi includes two or more sub-emission control lines, the sub-pixel circuit SPC may operate in response to emission control signals received through the corresponding two or more sub-emission control lines.

The sub-pixel circuit SPC may receive a data signal through the jth data line DLj. The sub-pixel circuit SPC may store a voltage corresponding to the data signal in response to at least one of the gate signals received through the first and/or second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light having a luminance corresponding to the data signal.

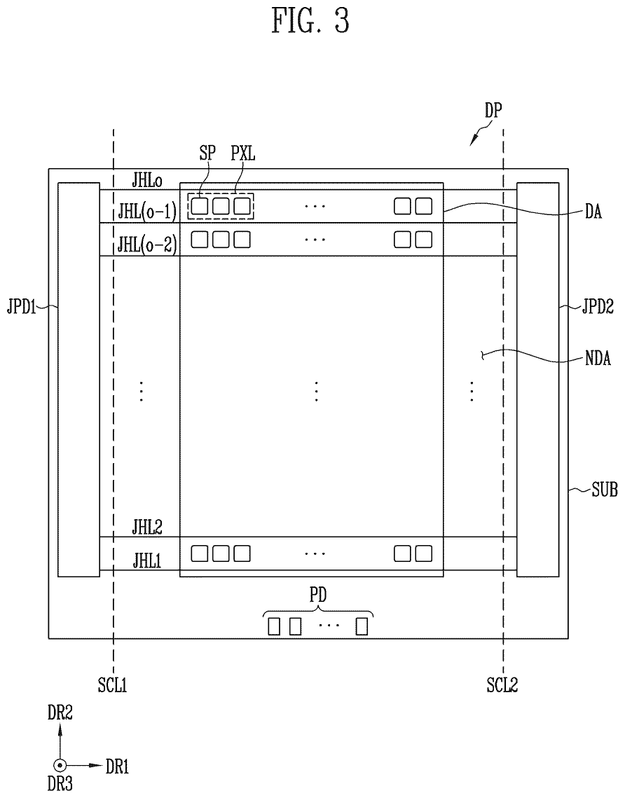

FIG. 3 is a plan view illustrating the display panel shown in FIG. 1 according to one or more embodiments.

Referring to FIG. 3, the display panel DP, which may correspond to the display panel 110 shown in FIG. 1, may include a display area DA and a non-display area NDA. The display panel DP may display an image through the display area DA. The non-display area NDA may be disposed at the periphery of the display area DA. For example, in some embodiments, the non-display area NDA may be adjacent to, or surround around the periphery of, the display area DA.

The display panel DP may include a substrate SUB, the sub-pixels SP, a first metal pad JPD1, a second metal pad JPD2, metal lines JHL1 to JHLo (where o is a natural number), and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located to be very close to (e.g., by a predetermined distance from) the eyes of a user. As such, the sub-pixels SP having a relatively high degree of integration may be desired. In order to increase the degree of integration of the sub-pixels SP, the substrate SUB may be provided as a silicon substrate. The sub-pixels SP and/or the display panel DP may be formed on the silicon substrate SUB. The display device 100 (e.g., see FIG. 1) including the display panel DP formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1, and a second direction DR2 intersecting or crossing the first direction DR1. However, the present disclosure is not limited thereto. For example, the sub-pixels SP may be arranged in a zigzag form along the first direction DR1 and the second direction DR2. For example, the plurality of sub-pixels SP may be disposed in an RGBG form (e.g., a PENTILE® form, PENTILE® being a duly registered trademark of Samsung Display Co., Ltd.). The first direction DR1 may be a row direction, and the second direction DR2 may be a column direction.

Two or more sub-pixels from among the sub-pixels SP may constitute one pixel PXL.

The substrate SUB may include a display area DA and a non-display area NDA. A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn shown in FIG. 1, may be space-efficiently disposed in the non-display area NDA.

The first metal pad JPD1 may be disposed in the non-display area NDA. The first metal pad JPD1 may have a rectangular or an approximately rectangular shape including long sides extending in the second direction DR2 and short sides extending in the first direction DR1. A length of the long side may be the same or similar to a length of the display area DA in the second direction DR2. The first metal pad JPD1 may include at least one metal material. For example, the first metal pad JPD1 may include a suitable material having a high resistivity and a high melting point, such as molybdenum (Mo), titanium (Ti), or titanium nitride (TiN). The first metal pad JPD1 may be located in the opposite direction of the first direction DR1 from the display area DA.

The second metal pad JPD2 may be located in the non-display area NDA, and may be located in the first direction DR1 from the first metal pad JPD1. The second metal pad JPD2 may have a rectangular or an approximately rectangular shape including long sides extending in the second direction DR2 and short sides extending in the first direction DR1. A length of the long side may be the same or similar to the length of the display area DA in the second direction DR2. The second metal pad JPD2 may include at least one metal material. For example, the second metal pad JPD2 may include a suitable material having a high resistivity and a high melting point, such as molybdenum (Mo), titanium (Ti), or titanium nitride (TiN). The second metal pad JPD2 may be located in the first direction DR1 from the display area DA.

The metal lines JHL1 to JHLo may connect the first metal pad JPD1 and the second metal pad JPD2 to each other. Here, o may be an integer greater than 1. Each of the metal lines JHL1 to JHLo may extend in the first direction DR1, and may not overlap with the sub-pixels SP. As used herein, the phrase, “not overlapping with the sub-pixels SP” means not overlapping with emission areas of the sub-pixels SP. The metal lines JHL1 to JHLo may be arranged in parallel to each other in the second direction DR2. One ends of the metal lines JHL1 to JHLo may be connected to the first metal pad JPD1, and other ends (e.g., opposite ends) of the metal lines JHL1 to JHLo may be connected to the second metal pad JPD2. For example, the metal lines JHL1 to JHLo may include a suitable material having a high resistivity and a high melting point, such as molybdenum (Mo), titanium (Ti), or titanium nitride (TiN).

The first metal pad JPD1, the second metal pad JPD2, and the metal lines JHL1 to JHLo may be integrally formed of the same material through the same or substantially the same process as each other.

When a power voltage is applied to the first metal pad JPD1, heat may be generated in the metal lines JHL1 to JHLo due to Joule heating. The power voltage may be a single pulse, or may include a plurality of pulses. Due to the generated heat, an organic material that is adjacent to the metal lines JHL1 to JHLo may be sublimed.

A virtual first cutting line SCL1 may extend in the second direction DR2 between the first metal pad JPD1 and the display area DA. The first cutting line SCL1 may traverse the metal lines JHL1 to JHLo. A virtual second cutting line SCL2 may extend in the second direction DR2 between the second metal pad JPD2 and the display area DA. The second cutting line SCL2 may traverse the metal lines JHL1 to JHLo.

After a Joule heating process, as the display panel DP is cut along the cutting lines SCL1 and SCL2, the first metal pad JPD1 and the second metal pad JPD2 may not exist in a final product. In another embodiment, if the display panel DP is not cut along the cutting lines SCL1 and SCL2, the first metal pad JPD1 and the second metal pad JPD2 may exist in the final product.

At least one of the gate driver 120, the data driver 130, the voltage generator 140, the controller 150, and/or the temperature sensor 160 shown in FIG. 1 may be integrated in the non-display area NDA of the display panel DP. In one or more embodiments, the gate driver 120 shown in FIG. 1 is mounted at (e.g., in or on) the display panel DP, and may be disposed in the non-display area NDA. In other embodiments, the gate driver 120 may be implemented as an integrated circuit distinguished from the display panel DP. In embodiments, the temperature sensor 160 may be disposed in the non-display area NDA to sense the temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (e.g., see FIG. 1). In one or more embodiments, voltages and signals, which are used for operations of the components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted at (e.g., in or on) the display panel DP, the gate control signal GCS may be transmitted from the driver integrated circuit DIC to the gate driver 120 through the pads PD.

In one or more embodiments, a circuit board may be electrically connected to the pads PD through (e.g., using) a conductive adhesive member, such as an anisotropic conductive film. The circuit board may be a Flexible Printed Circuit Board (FPCB) or a flexible film, which includes a flexible material. The driver integrated circuit DIC may be mounted on the circuit board to be electrically connected to the pads PD.

In embodiments, the display area DA may have various suitable shapes. The display area DA may have a closed-loop shape including linear sides and/or curved sides. For example, the display area DA may have a polygon shape, a circle shape, a semicircle shape, or an ellipse shape.

In one or more embodiments, the display panel DP may have a flat or substantially flat display surface. In other embodiments, the display panel DP may at least partially have a rounded display surface. In one or more embodiments, the display panel DP may be bendable, foldable, or rollable. The display panel DP and/or the substrate SUB may include one or more suitable materials having flexibility.

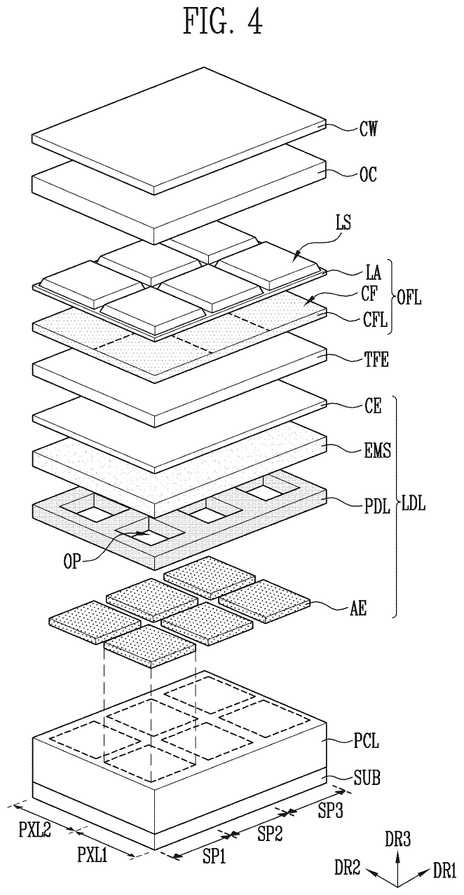

FIG. 4 is an exploded perspective view illustrating a portion of the display panel shown in FIG. 3. In FIG. 4, for convenience of illustration, a portion of the display panel DP corresponding to two pixels PXL1 and PXL2 from among the pixels PXL shown in FIG. 3 is schematically illustrated. A portion of the display panel DP corresponding to the other pixels PXL may also be configured in the same or similar way, and thus, redundant description thereof may not be repeated.

Referring to FIGS. 3 and 4, a first pixel PXL1 may include first to third sub-pixels SP1, SP2, and SP3. A second pixel PXL2 may include fourth to sixth sub-pixels having the same or substantially the same shape as those of the first to third sub-pixels SP1, SP2, and SP3. However, the present disclosure is not limited thereto. For example, each of the first and second pixels PXL1 and PXL2 may include four sub-pixels or two sub-pixels.

In FIG. 4, the first to third sub-pixels SP1, SP2, and SP3 are illustrated as having quadrangular shapes when viewed in a third direction DR3 (e.g., in a plan view) intersecting or crossing the first and second directions DR1 and DR2, and having the same size as each other. However, the present disclosure is not limited thereto. The first to third sub-pixels SP1, SP2, and SP3 may be variously modified to have various suitable shapes.

The display panel DP may include the substrate SUB, a pixel circuit layer PCL, a light emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may serve as at least some of circuit elements, lines, and/or the like. The conductive patterns may include copper, but the present disclosure is not limited thereto.

The circuit elements may include a sub-pixel circuit SPC (e.g., see FIG. 2) of each of the first to third sub-pixels SP1, SP2, and SP3. The sub-pixel circuit SPC may include a plurality of transistors, and one or more capacitors. Each transistor may include a semiconductor portion including a source region, a drain region, and a channel region, and a gate electrode overlapping with the semiconductor portion. In one or more embodiments, when the substrate SUB is provided as a silicon substrate, the semiconductor portion may be included in the substrate SUB, and the gate electrode may be included as a conductive pattern of the pixel circuit layer PCL (e.g., in the pixel circuit layer PCL). In one or more embodiments, when the substrate SUB is provided as a glass substrate or a PI substrate, the semiconductor portion and the gate electrode may be included in the pixel circuit layer PCL. Each capacitor may include electrodes that are spaced apart from each other. For example, each capacitor may include the electrodes that are spaced apart from each other on a plane (e.g., in a plan view) defined by the first and second directions DR1 and DR2. For example, the capacitor may include the electrodes that are spaced apart from each other in the third direction DR3, with an insulating layer interposed therebetween.

The lines of the pixel circuit layer PCL may include signal lines (e.g., a gate line, an emission control line, a data line, and the like), which are connected to each of the sub-pixels. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but the present disclosure is not limited thereto.

The pixel defining layer PDL may be disposed on the anode electrodes AE. The pixel defining layer PDL may include openings OP exposing a portion of each of the anode electrodes AE. One opening OP of the pixel defining layer PDL may be understood as an emission area of a corresponding one of the first to third sub-pixels SP1 to SP3.

In one or more embodiments, the pixel defining layer PDL may include an inorganic material. The pixel defining layer PDL may include a plurality of stacked inorganic layers. For example, the pixel defining layer PDL may include silicon oxide (SiOₓ) and/or silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer to generate light, an electron transport layer to transport electrons, a hole transport layer to transport holes, and the like.

In one or more embodiments, the light emitting structure EMS fills the openings OP of the pixel defining layer PDL, and may be entirely disposed on the top of the pixel defining layer PDL. In other words, the light emitting structure EMS may extend throughout the first to third sub-pixels SP1 to SP3. At least some of the layers in the light emitting structure EMS may be cut or curved at boundaries between the sub-pixels SP. However, the present disclosure is not limited thereto. For example, portions of the light emitting structure EMS, which correspond to the sub-pixels SP, may be separated (e.g., spaced apart) from each other, and each of the portions may be disposed in a corresponding opening OP of the pixel defining layer PDL.

The cathode electrode CE may be disposed on the light emitting structure EMS. The cathode electrode CE may extend throughout the sub-pixels SP. As such, the cathode electrode CE may be provided as a common electrode for the sub-pixels SP.

The cathode electrode CE may be a thin metal layer having a thickness in a degree to which light emitted from the light emitting structure EMS can be transmitted therethrough. The cathode electrode CE may be formed of a metal material to have a relatively thin thickness, or may be formed of a transparent conductive material. In one or more embodiments, the cathode electrode CE may include at least one of various suitable transparent conductive materials including indium tin oxide, indium zinc oxide, indium tin zinc oxide, aluminum zinc oxide, gallium zinc oxide, zinc tin oxide, and/or gallium tin oxide. In other embodiments, the cathode electrode CE may include at least one of silver (Ag), magnesium (Mg), and/or suitable mixtures thereof. However, the material of the cathode electrode CE is not limited thereto.

Any one of the anode electrodes AE, a portion of the light emitting structure EMS, which overlaps therewith, and a portion of the cathode electrode CE, which overlaps therewith, constitute one light emitting element LD (e.g., see FIG. 2). Each of light emitting elements LD of the sub-pixels SP may include one anode electrode AE, a portion of the light emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into a light emitting layer of the light emitting structure EMS to form excitons, and light may be generated when the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed over the cathode electrode CE. The encapsulation layer TFE may cover the light emitting element layer LDL and/or the pixel circuit layer PCL. The encapsulation layer TFE may prevent or substantially prevent oxygen and/or moisture from infiltrating into the light emitting element layer LDL. In one or more embodiments, the encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material, such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

In order to improve encapsulation efficiency of the encapsulation layer TFE, the encapsulation layer TFE may further include a thin film including aluminum oxide (AlOₓ). The thin film including aluminum oxide may be located on a top surface of the encapsulation layer TFE, which faces the optical functional layer OFL, and/or on a bottom surface of the encapsulation layer TFE, which faces the light emitting element layer LDL.

The thin film including aluminum oxide may be formed through an Atomic Layer Deposition (ALD) process. However, the present disclosure is not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter light emitted from the light emitting structure EMS, thereby selectively outputting light of a desired wavelength band or color, which corresponds to each sub-pixel. The color filter layer CFL may include color filters CF respectively corresponding to the sub-pixels. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to the light (e.g., the color of light) emitted from the light emitting structure EMS in each sub-pixel SP, at least some of the color filters CF may be omitted.

The lens array LA may be disposed on the color filter layer CFL. The lens array LA may include lenses LS respectively corresponding to the sub-pixels. Each of the lenses LS may output light emitted from the light emitting structure EMS along an intended path, thereby improving light emission efficiency. The lens array LA may have a relatively high refractive index. For example, the lens array LA may have a refractive index higher than a refractive index of the overcoat layer OC. In one or more embodiments, the lenses LS may include an organic material. In one or more embodiments, the lenses LS may include an acryl-based material. However, the material of the lenses LS is not limited thereto.

In one or more embodiments, compared with the opening OP of the pixel defining layer PDL, at least some of the color filters CF of the color filter layer CFL and at least some of the lenses LS of the lens array LA may be shifted in a direction parallel to or substantially parallel to a plane defined by the first and second directions DR1 and DR2. In more detail, in a central area of the display area DA, the center of the color filter CF and the center of the lens LS may be aligned or overlap with the center of a corresponding opening OP of the pixel defining layer PDL when viewed in the third direction DR3 (e.g., in a plan view). For example, in the central area of the display area DA, the opening OP of the pixel defining layer PDL may completely overlap with a corresponding color filter CF of the color filter layer CFL and a corresponding lens LS of the lens array LA. In an area adjacent to the non-display area NDA of the display area DA, the center of the color filter CF and the center of the lens LS may be shifted in a plane direction from the center of a corresponding opening OP of the pixel defining layer PDL when viewed in the third direction DR3 (e.g., in a plan view). For example, in an area adjacent to the non-display area NDA of the display area DA, the opening OP of the pixel defining layer PDL may partially overlap with a corresponding color filter of the color filter layer CFL and a corresponding lens of the lens array LA. Accordingly, at the center of the display area DA, light emitted from the light emitting structure EMS may be efficiently output in a normal direction of the display surface. At an outer portion of the display area DA, light emitted from the light emitting structure EMS may be efficiently output in a direction inclined by an angle (e.g., a predetermined angle) with respect to the normal direction.

The overcoat layer OC may be disposed over the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting the lower layers thereof from foreign matters, such as dust and moisture. For example, the overcoat layer OC may include at least one of an inorganic insulating layer and/or an organic insulating layer. For example, the overcoat layer OC may include epoxy, but the present disclosure is not limited thereto. The overcoat layer OC may have a refractive index lower than a refractive index of the lens array LA.

The cover window CW may be disposed on the overcoat layer OC. The cover window CW may protect the lower layers thereof. The cover window CW may have a refractive index higher than the refractive index of the overcoat layer OC. The cover window CW may include glass, but the present disclosure is not limited thereto. For example, the cover window CW may be an encapsulation glass to protect the components disposed on the bottom thereof. In other embodiments, the cover window CW may be omitted as needed or desired.

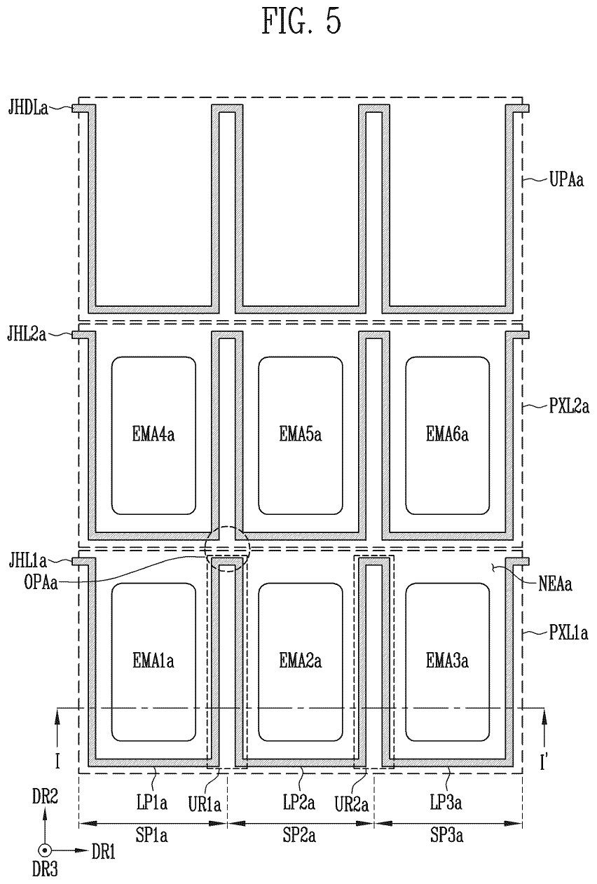

FIG. 5 is a plan view illustrating the pixels shown in FIG. 4 according to one or more embodiments. In FIG. 5, for convenience of illustration, a first pixel PXL1a and a second pixel PXL2a are illustrated. The other pixels PXL may be configured in the same or similar way as that of the first pixel PXL1a and the second pixel PXL2a.

The first pixel PXL1a may include a first sub-pixel SP1a, a second sub-pixel SP2a, and a third sub-pixel SP3a, which are arranged along the first direction DR1. The first sub-pixel SP1a may include a first emission area EMA1a, and a non-emission area NEAa at a periphery of the first emission area EMA1a. The second sub-pixel SP2a may include a second emission area EMA2a, and the non-emission area NEAa at a periphery of the second emission area EMA2a. The third sub-pixel SP3a may include a third emission area EMA3a, and the non-emission area NEAa at a periphery of the third emission area EMA3a.

The first emission area EMA1a may be an area in which light is emitted from a portion of the light emitting structure EMS (e.g., see FIG. 4), which corresponds to the first sub-pixel SP1a. The second emission area EMA2a may be an area in which light is emitted from a portion of the light emitting structure EMS, which corresponds to the second sub-pixel SP2a. The third emission area EMA3a may be an area in which light is emitted from a portion of the light emitting structure EMS, which corresponds to the third sub-pixel SP3a. As described above with reference to FIG. 4, each emission area may be understood as a corresponding opening OP of the pixel defining layer PDL, which corresponds to one of the first to third sub-pixels SP1a, SP2a, and SP3a. The shapes and areas of the first to third emission areas EMA1a, EMA2a, and EMA3a may be the same or substantially the same as each other. For example, each of the first to third emission areas EMA1a, EMA2a, and EMA3a may be provided in a rectangular shape or a square shape.

The second pixel PXL2a may include a fourth sub-pixel, a fifth sub-pixel, and a sixth sub-pixel, which are arranged along the first direction DR1. The second pixel PXL2a may be located in the second direction DR2 from the first pixel PXL1a. The fourth sub-pixel may include a fourth emission area EMA4a, the fifth sub-pixel may include a fifth emission area EMA5a, and the sixth sub-pixel may include a sixth emission area EMA6a. A configuration of the second pixel PXL2a is the same or substantially the same as the configuration of the first pixel PXL1a, and therefore, redundant description thereof may not be repeated.

A plurality of metal lines JHL1a, JHL2a, and JHDLa may each extend in the first direction DR1, and may not overlap with the emission areas of the sub-pixels SP. The metal lines JHL1a, JHL2a, and JHDLa may include metal patterns protruding in a direction intersecting or crossing the first direction DR1 between the emission areas.

A first metal line JHL1a may include line portions LP1a, LP2a, and LP3a, and metal patterns UR1a and UR2a. A first metal pattern UR1a may protrude in the second direction DR2 intersecting or crossing the first direction DR1 between the first emission area EMA1a and the second emission area EMA2a. A second metal pattern UR2a may protrude in the second direction DR2 between the second emission area EMA2a and the third emission area EMA3a.

Each of the metal patterns UR1a and UR2a may have a ring shape. The metal patterns UR1a and UR2a may be configured in the shape of a ‘-’ Korean character, or may be configured in the shape of a ‘U’ in the English alphabet. The metal patterns UR1a and UR2a may sublime an organic material of an area OPAa between and not overlapping with the first metal line JHL1a and a second metal line JHL2a, thereby preventing or reducing a leakage current through an organic material common layer between adjacent sub-pixels SP. For example, the first metal pattern UR1a may prevent or reduce a leakage current between the first sub-pixel SP1a and the second sub-pixel SP2a, and the second metal pattern UR2a may prevent or reduce a leakage current between the second sub-pixel SP2a and the third sub-pixel SP3a.

A length of each of the first metal pattern UR1a and the second metal pattern UR2a in the second direction DR2 may be longer than a length of each of the first emission area EMA1a, the second emission area EMA2a, and the third emission area EMA3a in the second direction DR2.

A first line portion LP1a may be located in the opposite direction of the second direction DR2 from the first emission area EMA1a, and may be connected to one end of the first metal pattern UR1a. A length of the first line portion LP1a in the first direction DR1 may be longer than a length of the first emission area EMA1a in the first direction DR1. A second line portion LP2a may be located in the opposite direction of the second direction DR2 from the second sub-pixel SP2a, and may connect the first metal pattern UR1a and the second metal pattern UR2a to each other.

A length of the second line portion LP2a in the first direction DR1 may be longer than a length of the second emission area EMA2a in the first direction DR1. A third line portion LP3a may be located in the opposite direction of the second direction DR2 from the third emission area EMA3a, and may be connected to another end (e.g., an opposite end) of the second metal pattern UR2a. A length of the third line portion LP3a in the first direction DR1 may be longer than a length of the third emission area EMA3a in the first direction DR1.

The second metal line JHL2a may traverse between the first emission area EMA1a and the fourth emission area EMA4a, between the second emission area EMA2a and the fifth emission area EMA5a, and between the third emission area EMA3a and the sixth emission area EMA6a. The first metal line JHL1a and the second metal line JHL2a may be spaced apart from each other in the second direction DR2.

A dummy metal line JHDLa may be located in the second direction DR2 of the sub-pixels SP located at an outermost portion in the second direction DR2 from among the sub-pixels SP. For example, in FIG. 5, the fourth to sixth sub-pixels of the second pixel PXL2a are illustrated as the sub-pixels SP located at the outermost portion in the second direction DR2. An upper area UPAa located in the second direction DR2 from the second pixel PXL2a may correspond to the non-display area NDA, and may not include any sub-pixels SP (or any emission areas thereof). The dummy metal line JHDLa may be located in the second direction DR2 from the fourth to sixth sub-pixels, so that a leakage current in the second direction DR2 from the fourth to sixth sub-pixels can be prevented or reduced. Both ends (e.g., opposite ends) of the dummy metal line JHDLa may be connected to the first metal pad JPD1 and the second metal pad JPD2, respectively, and may be supplied with a power voltage, like the other metal lines JHL1a and JHL2a.

Shapes of the first metal line JHL1a, the second metal line JHL2a, and the dummy metal line JHDLa may be the same or substantially the same as each other. Therefore, resistance values of the first metal line JHL1a, the second metal line JHL2a, and the dummy metal line JHDLa may be the same or substantially the same as each other, and Joule heating may be uniformly or substantially uniformly generated.

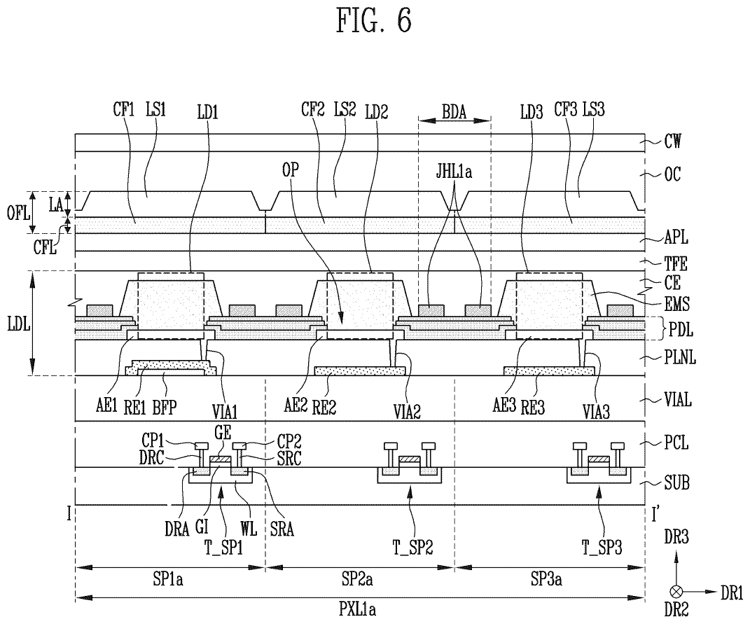

FIG. 6 is a sectional view taken along the line I-I′ shown in FIG. 5.

Referring to FIG. 6, the pixel circuit layer PCL may be disposed on the substrate SUB.

The substrate SUB may include a silicon wafer substrate formed using a semiconductor process. For example, the substrate SUB may include silicon, germanium, and/or silicon-germanium.

The substrate SUB and the pixel circuit layer PCL disposed on the substrate SUB may include circuit elements of each of the first to third sub-pixels SP1a to SP3a. For example, the substrate SUB and the pixel circuit layer PCL may include a transistor T_SP1 of the first sub-pixel SP1a, a transistor T_SP2 of the second sub-pixel SP2a, and a transistor T_SP3 of the third sub-pixel SP3a. The transistor T_SP1 of the first sub-pixel SP1a may be any one of the transistors included in a sub-pixel circuit SPC (e.g., see FIG. 2) of the first sub-pixel SP1a. The transistor T_SP2 of the second sub-pixel SP2a may be any one of the transistors included in a sub-pixel circuit SPC of the second sub-pixel SP2a. The transistor T_SP3 of the third sub-pixel SP3a may be any one of the transistors included in a sub-pixel circuit SPC of the third sub-pixel SP3a. In FIG. 6, for convenience of illustration, one of the transistors for each of the sub-pixels is illustrated, and the other circuit elements are not shown.

The transistor T_SP1 of the first sub-pixel SP1a may include a source region SRA, a drain region DRA, and a gate electrode GE.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap with the channel region between the source region SRA and the drain region DRA, and may be disposed in the pixel circuit layer PCL. The gate electrode GE may be spaced apart from the well WL and/or the channel region by a suitable insulating material, such as a gate insulating layer GI. The gate electrode GE may include a conductive material.

A plurality of layers included in the pixel circuit layer PCL may include insulating layers, and conductive patterns disposed between the insulating layers. The conductive patterns may include first and second conductive patterns CP1 and CP2. The first conductive pattern CP1 may be electrically connected to the drain region DRA through a drain connection portion DRC penetrating one or more of the insulating layers. The second conductive pattern CP2 may be electrically connected to the source region SRA through a source connection portion SRC penetrating one or more of the insulating layers.

Because the gate electrode GE and the first and second conductive patterns CP1 and CP2 may be connected to other circuit elements and/or lines, the transistor T_SP1 of the first sub-pixel SP1a may be provided as (e.g., may correspond to) any one of the transistors of the first sub-pixel SP1a.

Each of the transistor T_SP2 of the second sub-pixel SP2a and the transistor T_SP3 of the third sub-pixel SP3a may be configured in the same or substantially the same way as that of the transistor T_SP1 of the first sub-pixel SP1a.

As such, the substrate SUB and the pixel circuit layer PCL may include circuit elements of each of the first to third sub-pixels SP1a to SP3a.

A via layer VIAL may be disposed on the pixel circuit layer PCL. The via layer VIAL covers the pixel circuit layer PCL, and may have an entirely flat surface. The via layer VIAL may be configured to planarize or substantially planarize step differences on the pixel circuit layer PCL. The via layer VIAL may include at least one of silicon oxide (SiOₓ), silicon nitride (SiNₓ), and/or silicon carbon nitride (SiCN), but the present disclosure is not limited thereto.

A light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 are disposed in the first to third sub-pixels SP1a to SP3a, respectively. Each of the first to third reflective electrodes RE1 to RE3 may be in contact with a circuit element disposed in the pixel circuit layer PCL through a via (e.g., a via hole) penetrating the via layer VIAL.

The first to third reflective electrodes RE1 to RE3 may serve as full mirrors, which reflect light emitted from the light emitting structure EMS toward a display surface (e.g., a cover window CW). The first to third reflective electrodes RE1 to RE3 may include a metal material suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), and/or suitable alloys of two or more materials selected therefrom. However, the present disclosure is not limited thereto.

In one or more embodiments, a connection electrode may be disposed on the bottom of each of the first to third reflective electrodes RE1 to RE3. The connection electrode may improve an electrical connection characteristic between a corresponding reflective electrode and a circuit element of the pixel circuit layer PCL. The connection electrode may have a multi-layered structure. The multi-layered structure may include titanium (Ti), titanium nitride (TiN), tantalum nitride (TaN), and the like, but the present disclosure is not limited thereto. In one or more embodiments, a corresponding reflective electrode may be located between multiple layers of the connection electrode.

A buffer pattern BFP may be disposed on the bottom of at least one of the first to third reflective electrodes RE1 to RE3. The buffer pattern BFP may include an inorganic material, such as silicon carbon nitride, but the present disclosure is not limited thereto. As the buffer pattern BFP is disposed, a height of a corresponding reflective electrode in the third direction DR3 may be adjusted. For example, the buffer pattern BFP may be disposed between the first reflective electrode RE1 and the via layer VIAL to adjust the height of the first reflective electrode RE1.

The first to third reflective electrodes RE1 to RE3 may serve as full mirrors, and the cathode electrode CE may serve as a half mirror. Light emitted from a light emitting layer of the light emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of the light emitted from a light emitting layer of a corresponding light emitting structure EMS.

By the buffer pattern BFP, the first sub-pixel SP1a may have a resonance distance shorter than a resonance distance of another sub-pixel. The resonance distance that is adjusted as described above may allow light of a specific wavelength range (e.g., a red color) to be effectively and efficiently amplified. Accordingly, the first sub-pixel SP1a may effectively and efficiently emit light of the corresponding wavelength range.

In FIG. 6, the buffer pattern BFP is illustrated as being provided to the first sub-pixel SP1a, but not provided to the second and third sub-pixels SP2a and SP3a. However, the present disclosure is not limited thereto. In some embodiments, the buffer pattern may also be provided in at least one of the second and/or third sub-pixels SP2a and/or SP3a to adjust a resonance distance of the at least one of the second and/or third sub-pixels SP2a and/or SP3a. For example, the first to third sub-pixels SP1a to SP3a may correspond to red, green, and blue, respectively, and thus, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize or substantially planarize step differences between the first to third reflective electrodes RE1 to RE3, the planarization layer PLNL may be disposed on the via layer VIAL and the first to third reflective electrodes RE1 to RE3. The planarization layer PLNL entirely covers the first to third reflective electrodes RE1 to RE3 and the via layer VIAL, and may have a flat or substantially flat surface (e.g., upper surface). In one or more embodiments, the planarization layer PLNL may be omitted as needed or desired.

On the planarization layer PLNL, the first to third anode electrodes AE1 to AE3 overlapping with the first to third reflective electrodes RE1 to RE3, respectively, may be disposed. The first to third anode electrodes AE1 to AE3 may have shapes the same as or similar to the shapes of the first to third emission areas EMA1a to EMA3a shown in FIG. 5 when viewed in the third direction DR3 (e.g., in a plan view). The first to third anode electrodes AE1 to AE3 may be connected to the first to third reflective electrodes RE1 to RE3, respectively. The first anode electrode AE1 may be connected to the first reflective electrode RE1 through a first via VIA1 penetrating the planarization layer PLNL. The second anode electrode AE2 may be connected to the second reflective electrode RE2 through a second via VIA2 penetrating the planarization layer PLNL. The third anode electrode AE3 may be connected to the third reflective electrode RE3 through a third via VIA3 penetrating the planarization layer PLNL.

In one or more embodiments, the first to third anode electrodes AE1 to AE3 may include at least one of various suitable transparent conductive materials, such as indium tin oxide (ITO), indium zinc oxide (IZO), zinc oxide (ZnOₓ), indium gallium zinc oxide (IGZO), and/or indium tin zinc oxide (ITZO). However, the material of the first to third anode electrodes AE1 to AE3 is not limited thereto. For example, the first to third anode electrodes AE1 to AE3 may include titanium nitride.

In one or more embodiments, an insulating layer for adjusting a height of one or more of the first to third anode electrodes AE1 to AE3 may be further provided. The insulating layer may be disposed between at least one of the first to third anode electrodes AE1 to AE3 and a corresponding reflective electrode. The planarization layer PLNL and/or the buffer pattern BFP may be omitted as needed or desired. For example, the first to third sub-pixels SP1a to SP3a may correspond to red, green, and blue, respectively, and thus, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL may be disposed on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define an emission area of each of the first to third sub-pixels SP1a to SP3a. As such, the pixel defining layer PDL may define the first to third emission areas EMA1a to EMA3a shown in FIG. 5, while being disposed in the non-emission area NEA shown in FIG. 5.

In one or more embodiments, the pixel defining layer PDL may include a plurality of inorganic insulating layers. Each of the plurality of inorganic insulating layers may include at least one of silicon oxide (SiOₓ) and/or silicon nitride (SiNₓ). For example, the pixel defining layer PDL may include first to third inorganic insulating layers, which are sequentially stacked, and each of the first to third inorganic insulating layers may include silicon nitride, silicon oxide, and/or silicon oxynitride. However, the present disclosure is not limited thereto. The first to third inorganic insulating layers may have a step-shaped section in an area adjacent to the opening OP.

In a boundary area BDA between the sub-pixels that are adjacent to each other, the first metal line JHL1a may be provided. Each of the metal lines including the first metal line JHL1a may be located on the pixel defining layer PDL.

In the display area DA, each of the metal lines including the first metal line JHL1a may be in contact with the cathode electrode CE of the light emitting elements of the sub-pixels SP. For example, the metal lines may radiate heat caused by Joule heating after the light emitting structure EMS is stacked, thereby subliming a portion of the light emitting structure EMS, which is located in the vicinity thereof. Thus, a leakage current through cut portions of the light emitting structure EMS may be prevented or substantially prevented by the metal lines. The metal lines may be exposed to the outside of the light emitting structure EMS, and may be in contact with the cathode electrode CE deposited subsequently thereon.

The light emitting structure EMS may be disposed on the anode electrodes AE exposed by the openings OP of the pixel defining layer PDL. In one or more embodiments, the light emitting structure EMS may be formed through a suitable process, such as vacuum deposition or inkjet printing. The light emitting structure EMS fills the opening OP of the pixel defining layer PDL, and may be entirely disposed throughout the first to third sub-pixels SP1a to SP3a. As described above, the light emitting structure EMS may be at least partially cut in the boundary area BDA by the first metal line JHL1a. Accordingly, during an operation of the display panel DP, a current leaked from each of the first to third sub-pixels SP1a to SP3a to a sub-pixel adjacent thereto through layers included in the light emitting structure EMS may be decreased. Thus, first to third light emitting elements LD1 to LD3 may operate with relatively high reliability.

The cathode electrode CE may be disposed over the light emitting structure EMS. The cathode electrode CE may be commonly provided in the first to third sub-pixels SP1a to SP3a. The cathode electrode CE may serve as a half mirror to allow light emitted from the light emitting structure EMS to be partially transmitted therethrough, and to be partially reflected therefrom.

The first anode electrode AE1, a portion of the light emitting structure EMS, which overlaps with the first anode electrode AE1, and a portion of the cathode electrode CE, which overlaps with the first anode electrode AE1, may constitute the first light emitting element LD1. The second anode electrode AE2, a portion of the light emitting structure EMS, which overlaps with the second anode electrode AE2, and a portion of the cathode electrode CE, which overlaps with the second anode electrode AE2, may constitute the second light emitting element LD2. The third anode electrode AE3, a portion of the light emitting structure EMS, which overlaps with the third anode electrode AE3, and a portion of the cathode electrode CE, which overlaps with the third anode electrode AE3, may constitute the third light emitting element LD3.

The encapsulation layer TFE may be disposed over the cathode electrode CE. The encapsulation layer TFE may prevent or substantially prevent oxygen and/or moisture from infiltrating into the light emitting element layer LDL.

An optical functional layer OFL may be disposed on the encapsulation layer TFE. In one or more embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA. The color filter layer CFL may include first to third color filters CF1 to CF3 corresponding to the first to third sub-pixels SP1a to SP3a, respectively. The first to third color filters CF1 to CF3 may allow light having different wavelength ranges from each other to pass therethrough. For example, the first to third color filters CF1 to CF3 may allow light of red, green, and blue colors, respectively, to pass therethrough.

In one or more embodiments, the first to third color filters CF1 to CF3 may partially overlap with each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 corresponding to the first to third sub-pixels SP1a to SP3a, respectively. The first to third lenses LS1 to LS3 may output the light emitted from the first to third light emitting elements LD1 to LD3 along intended paths, respectively, thereby improving light emission efficiency.

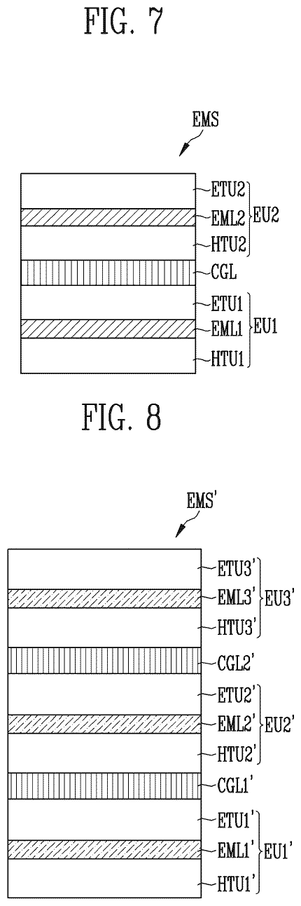

FIG. 7 is a sectional view illustrating a light emitting structure included in one of the first to third light emitting elements shown in FIG. 6 according to one or more embodiments.

Referring to FIG. 7, the light emitting structure EMS may have a tandem structure in which first and second light emitting units (e.g., first and second light emitting sub-structures) EU1 and EU2 are stacked. The light emitting structure EMS may have the same or substantially the same configuration in each of the first to third light emitting elements LD1 to LD3 shown in FIG. 6.

Each of the first and second light emitting units EU1 and EU2 may include a light emitting layer for generating light according to an applied current. The first light emitting unit EU1 may include a first light emitting layer EML1, a first electron transport unit (e.g., a first electron transport structure) ETU1, and a first hole transport unit (e.g., a first hole transport structure) HTU1. The first light emitting layer EML1 may be disposed between the first electron transport unit ETU1 and the first hole transport unit HTU1. The second light emitting unit EU2 may include a second light emitting layer EML2, a second electron transport unit (e.g., a second electron transport structure) ETU2, and a second hole transport unit (e.g., a second hole transport structure) HTU2. The second light emitting layer EML2 may be disposed between the second electron transport unit ETU2 and the second hole transport unit HTU2.

Each of the first and second hole transport units HTU1 and HTU2 may include at least one of a hole injection layer and/or a hole transport layer. Each of the first and second hole transport units HTU1 and HTU2 may further include a hole buffer layer, an electron blocking layer, and/or the like as desired or necessary. The first and second hole transport units HTU1 and HTU2 may have the same or substantially the same configuration as each other, or may have different configurations from each other.

Each of the first and second electron transport units ETU1 and ETU2 may include at least one of an electron injection layer and/or an electron transport layer. Each of the first and second electron transport units ETU1 and ETU2 may further include an electron buffer layer, a hole blocking layer, and the like as desired or necessary. The first and second electron transport units ETU1 and ETU2 may have the same or substantially the same configuration as each other, or may have different configurations from each other.

A connection layer provided in the form of a charge generation layer CGL may be disposed between the first light emitting unit EU1 and the second light emitting unit EU2 to electrically connect the first light emitting unit EU1 and the second light emitting unit EU2 to each other. In one or more embodiments, the charge generation layer CGL may have a stacked structure of a p-dopant layer and an n-dopant layer. For example, the p-dopant layer may include a p-type dopant, such as HAT-CN, TCNQ, or NDP-9, and the n-dopant layer may include an alkali metal, an alkali earth metal, a lanthanide-based metal, or any suitable combination thereof. However, the present disclosure is not limited thereto.

In one or more embodiments, the first light emitting layer EML1 and the second light emitting layer EML2 may generate light of different colors from each other. The light respectively emitted from the first light emitting layer EML1 and the second light emitting layer EML2 may be mixed together to be viewed as white light. For example, the first light emitting layer EML1 may generate light of a blue color, and the second light emitting layer EML2 may generate light of a yellow color. In one or more embodiments, the second light emitting layer EML2 may include a structure in which a first sub-light emitting layer that generates light of a red color and a second sub-light emitting layer that generates light of a green color are stacked. The light of the red color and the light of the green color may be mixed together to provide the light of the yellow color. An intermediate layer that performs a function of transporting holes and/or a function of blocking transportation of electrodes may be further disposed between the first and second sub-light emitting layers.

In other embodiments, the first light emitting layer EML1 and the second light emitting layer EML2 may generate light of the same color as each other.

In one or more embodiments, the light emitting structure EMS may be formed through a suitable process, such as vacuum deposition or inkjet printing, but the present disclosure is not limited thereto.

FIG. 8 is a sectional view illustrating the light emitting structure included in one of the first to third light emitting elements shown in FIG. 6 according to one or more embodiments.

Referring to FIG. 8, a light emitting structure EMS' may a tandem structure in which first to third light emitting units (e.g., first to third light emitting sub-structures) EU1′ to EU3′ are stacked. The light emitting structure EMS' may have the same or substantially the same configuration in each of the first to third light emitting elements LD1 to LD3 shown in FIG. 6.

Each of the first to third light emitting units EU1′ to EU3′ may include a light emitting layer for generating light according to an applied current. The first light emitting unit EU1′ may include a first light emitting layer EML1′, a first electron transport unit (e.g., a first electron transport structure) ETU1′, and a first hole transport unit (e.g., a first hole transport structure) HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit (e.g., a second electron transport structure) ETU2′, and a second hole transport unit (e.g., a second hole transport structure) HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit (e.g., a third electron transport structure) ETU3′, and a third hole transport unit (e.g., a third hole transport structure) HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and/or a hole transport layer. Each of the first to third hole transport units HTU1′ to HTU3′ may further include a hole buffer layer, an electron blocking layer, and/or the like as desired or necessary. The first to third hole transport units HTU1′ to HTU3′ may have the same or substantially the same configuration as each other, or may have different configurations each other.

Each of the first to third electron transport units ETU1′ to ETU3′ may include at least one of an electron injection layer and/or an electron transport layer. Each of the first to third electron transport units ETU1′ to ETU3′ may further include an electron buffer layer, a hole blocking layer, and/or the like as desired or necessary. The first to third electron transport units ETU1′ to ETU3′ may have the same or substantially the same configuration as each other, or may have different configurations from each other.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In one or more embodiments, the first to third light emitting layers EML1′ to EML3′ may generate light of different colors from each other. The light respectively emitted from the first to third light emitting layers EML1′ to EML3′ may be mixed together to be viewed as white light. For example, the first light emitting layer EML1′ may generate light of a blue color, the second light emitting layer EML2′ may generate light of a green color, and the third light emitting layer EML3′ may generate light of a red color.

In other embodiments, the light emitting layers of at least two of the first to third light emitting layers EML1′ to EML3′ may generate light of the same color as each other.

However, the present disclosure is not limited thereto, and unlike the light emitting structures EMS and EMS' described above with reference to FIGS. 7 and 8, the light emitting structure EMS shown in FIG. 6 may include one light emitting unit (e.g., one light emitting sub-structure) in each of the first to third light emitting elements LD1 to LD3. The light emitting unit included in each of the first to third light emitting elements LD1 to LD3 may be configured to emit light of different colors from each other. For example, the light emitting unit of the first light emitting element LD1 may emit light of a red color, the light emitting unit of the second light emitting element LD2 may emit light of a green color, and the light emitting unit of the third light emitting element LD3 may emit light of a blue color. Further, the light emitting units of the first to third sub-pixels SP1a to SP3a may be separated (e.g., spaced apart) from each other, and each of the light emitting units may be disposed in a corresponding opening of the pixel defining layer PDL. In addition, in some embodiments, at least some of the color filters CF1 to CF3 may be omitted as needed or desired.

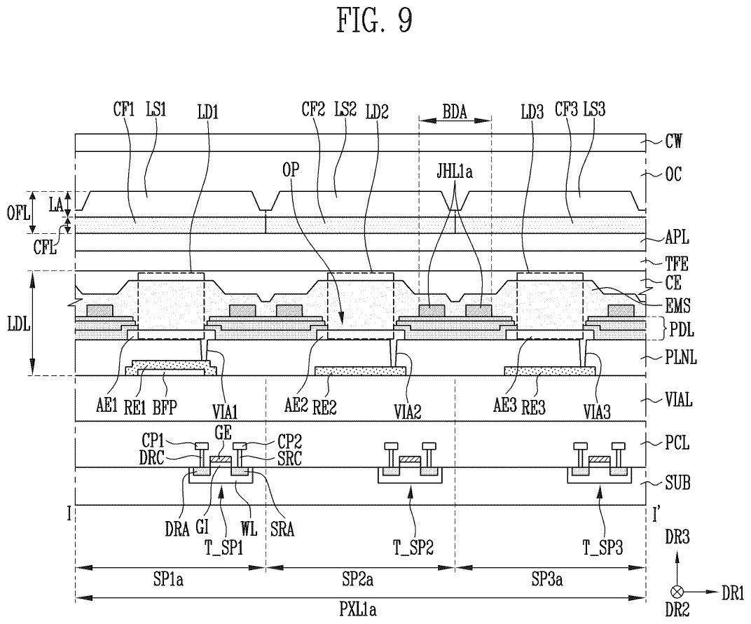

FIG. 9 is a sectional view taken along the line I-I′ shown in FIG. 5 according to one or more embodiments.

The light emitting structure EMS shown in FIG. 9 may be different from the light emitting structure EMS described above with reference to FIG. 6, in that a portion of the light emitting structure EMS in FIG. 9 may remain on the first metal line JHL1a. In other words, in the display area DA, each of the metal lines including the first metal line JHL1a may not be in contact with the cathode electrode CE of the light emitting elements of the sub-pixels.

For example, after the first light emitting unit EU1 and the charge generation layer CGL are stacked on the first metal line JHL1a, heat caused by Joule heating may be radiated in the first metal line JHL1a, and therefore, portions of the first light emitting unit EU1 and the charge generation layer CGL, which are located in the vicinity of the first metal line JHL1a, may be sublimed. Subsequently, stacking of the second light emitting unit EU2 may be performed (e.g., see FIG. 7).

In another example, after the first light emitting unit EU1′, the first charge generation layer CGL1′, the second light emitting unit EU2′, and the second charge generation layer CGL2′ are stacked on the first metal line JHL1a, heat caused by Joule heating may be radiated in the first metal line JHL1a, and therefore, portions of the first light emitting unit EU1′, the first charge generation layer CGL1′, the second light emitting unit EU2′, and the second charge generation layer CGL2′, which are located in the vicinity of the first metal line JHL1a, may be sublimed. Subsequently, stacking of the third light emitting unit EU3′ may be performed (e.g., see FIG. 8).

Because the charge generation layer CGL, the first charge generation layer CGL1′, or the second charge generation layer CGL2′ may be sublimed, a leakage current may be prevented or substantially prevented, even when a portion of the light emitting structure EMS remains.

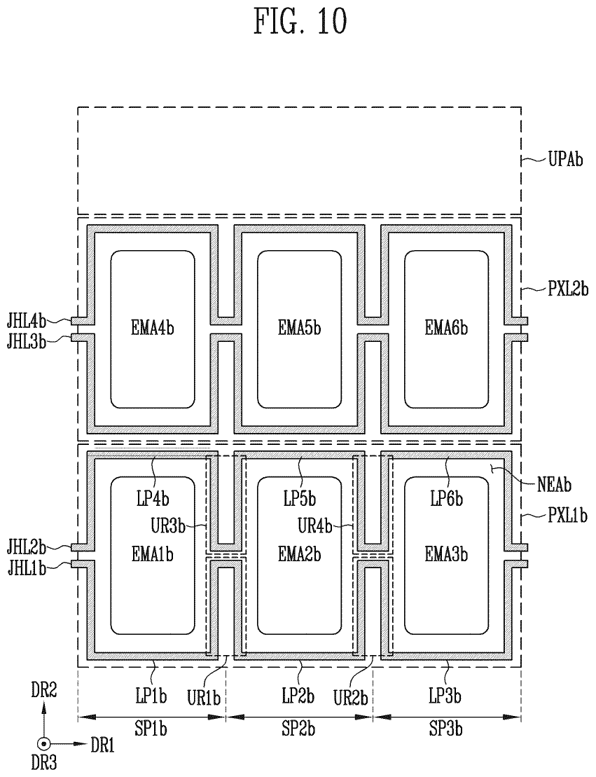

FIG. 10 is a view illustrating a differently configured metal line that is applied to the pixels shown in FIG. 5 according to one or more embodiments.

In FIG. 10, the configuration of the first pixel PXL1b, the first sub-pixel SP1b, the second sub-pixel SP2b, and the third sub-pixel SP3b may be the same or substantially the same as those described above with reference to FIG. 5, and thus, redundant description thereof may not be repeated. In addition, in FIG. 10, the configuration of the second pixel PXL2b and the fourth, fifth, and sixth sub-pixels may be the same or substantially the same as those described above with reference to FIG. 5, and thus, redundant description thereof may not be repeated.

Referring to FIG. 10, each of a plurality of metal lines JHL1b, JHL2b, JHL3b, and JHL4b may extend in the first direction DR1, and may not overlap with the emission areas EMA1b, EMA2b, EMA3b, EMA4b, EMA5b, and EMA6b of the sub-pixels. The plurality of metal lines JHL1b, JHL2b, JHL3b, and JHL4b may include metal patterns (e.g., UR1b and UR2b) protruding in a direction intersecting or crossing the first direction DR1 between the emission areas EMA1b, EMA2b, EMA3b, EMA4b, EMA5b, and EMA6b.

However, configurations of the metal lines JHL1b, JHL2b, JHL3b, and JHL4b shown in FIG. 10 may be different from the configurations of the metal lines JHL1a, JHL2a, and JHDLa described above with reference to FIG. 5. The metal lines shown in FIG. 10 may include a first group of metal lines JHL1b and JHL3b, and a second group of metal lines JHL2b and JHL4b. The first group of metal lines JHL1b and JHL3b and the second group of metal lines JHL2b and JHL4b may be alternately arranged along the second direction DR2. In an embodiment, the first group of metal lines JHL1b and JHL3b and the second group of metal lines JHL2b and JHL4b may have shapes that are symmetrical or substantially symmetrical to each other with respect to the second direction DR2.

The first group of metal lines JHL1b and JHL3b may include metal patterns protruding in the second direction DR2. For example, along the first direction DR1, the first metal line JHL1b may sequentially include a first line portion LP1b, a first metal pattern UR1b, a second line portion LP2b, a second metal pattern UR2b, and a third line portion LP3b. The first and second metal patterns UR1b and UR2b of the first metal line JHL1b may protrude in the second direction DR2 with respect to (e.g., from) the line portions LP1b, LP2b, and LP3b.

The second group of metal lines JHL2b and JHL4b may include metal patterns protruding in the opposite direction of the second direction DR2. For example, along the first direction DR1, a second metal line JHL2b may sequentially include a fourth line portion LP4b, a third metal pattern UR3b, a fifth line portion LP5b, a fourth metal pattern UR4b, and a sixth line portion LP6b. The third and fourth metal patterns UR3b and UR4b of the second metal line JHL2b may protrude in the opposite direction of the second direction DR2 with respect to (e.g., from) the line portions LP4b, LP5b, and LP6b.

The first metal pattern UR1b and the third metal pattern UR3b may face each other between the first emission area EMA1b and the second emission area EMA2b. Heat generated between the first metal pattern UR1b and the third metal pattern UR3b may remove an organic common layer between the first emission area EMA1b and the second emission area EMA2b. In more detail, a partial area that is not covered by the metal lines JHL1b and JHL2b may exist between the first emission area EMA1b and the second emission area EMA2b. However, unlike the line portions LP1b, LP2b, and LP3b configured with a single line, the metal patterns UR1b and UR3b configured with two lines may radiate a larger amount of heat, and accordingly, the organic common layer between the first emission area EMA1b and the second emission area EMA2b may be effectively removed. Thus, a leakage current between the first emission area EMA1b and the second emission area EMA2b may be prevented or reduced.

The second metal pattern UR2b and the fourth metal pattern UR4b may face each other between the second emission area EMA2b and the third emission area EMA3b. Heat generated in the second metal pattern UR2b and the fourth metal pattern UR4b may remove an organic common layer between the second emission area EMA2b and the third emission area EMA3b. In more detail, a partial area that is not covered by the metal lines JHL1b and JHL2b may exist between the second emission area EMA2b and the third emission area EMA3b. However, unlike the line portions LP1b, LP2b, and LP3b configured with a single line, the metal patterns UR2b and UR4b configured with two lines may radiate a larger amount of heat, and accordingly, the organic common layer between the second emission area EMA2b and the third emission area EMA3b may be effectively removed. Thus, a leakage current between the second emission area EMA2b and the third emission area EMA3b may be prevented or reduced.

In FIG. 10, an upper area UPAb in the non-display area NDA, which is located in the second direction DR2 from the second pixel PXL2b, may not include any dummy metal line, because the fourth metal line JHL4b located in the display area DA may prevent or substantially prevent a leakage current of the second pixel PXL2b in the second direction DR2.

Lengths of the metal lines JHL1b, JHL2b, JHL3b, and JHL4b may be the same or substantially the same as each other. Therefore, resistance values of the metal lines JHL1b, JHL2b, JHL3b, and JHL4b may be the same or substantially the same as each other, and heat may be uniformly generated in a Joule heating process.

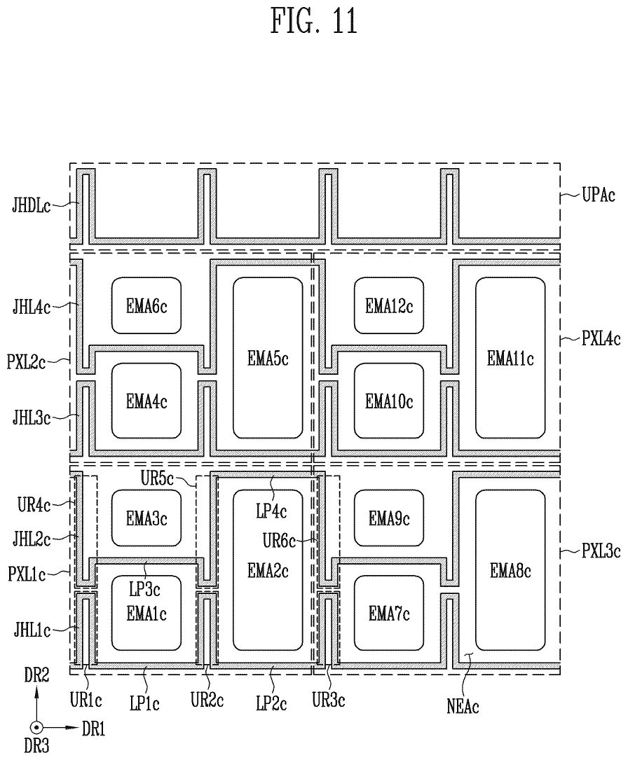

FIG. 11 is a view illustrating a metal line that is applied to another kind of pixels according to one or more embodiments.

Referring to FIG. 11, for convenience of illustration, an example of four pixels PXL1c, PXL2c, PXL3c, and PXL4c, and a plurality of metal lines JHL1c, JHL2c, JHL3c, JHL4c, and JHDLc corresponding thereto are shown.

A first pixel PXL1c may include a first sub-pixel, a second sub-pixel located in the first direction DR1 from the first sub-pixel, and a third sub-pixel located in the second direction DR2 from the first sub-pixel. The first sub-pixel may include a first emission area EMA1c, the second sub-pixel may include a second emission area EMA2c, and the third sub-pixel may include a third emission area EMA3c. A portion that does not correspond to the emission areas in the display area DA may be a non-emission area NEAc.

Similarly, a second pixel PXL2c may include a fourth sub-pixel having a fourth emission area EMA4c, a fifth sub-pixel having a fifth emission area EMA5c, and a sixth sub-pixel having a sixth emission area EMA6c. A third pixel PXL3c may include a seventh sub-pixel having a seventh emission area EMA7c, an eighth sub-pixel having an eighth emission area EMA8c, and a ninth sub-pixel having a ninth emission area EMA9c. A fourth pixel PXL4c may include a tenth sub-pixel having a tenth emission area EMA10c, an eleventh sub-pixel having an eleventh emission area EMA11c, and a twelfth sub-pixel having a twelfth emission area EMA12c.

Hereinafter, for convenience, the first pixel PXL1c will be mainly described in more detail. The second to fourth pixels PXL2c, PXL3c, and PXL4c and the other pixels that are not shown in FIG. 11 may have the same or substantially the same configuration as that of the first pixel PXL1c described in more detail hereinafter, and thus, redundant description thereof may not be repeated.

A length of the second emission area EMA2c in the second direction DR2 may be longer than a length of each of the first emission area EMA1c and the third emission area EMA3c in the second direction DR2. For example, an area of the second emission area EMA2c may be larger than an area of each of the first emission area EMA1c and the third emission area EMA3c. In some embodiments, an area of the first emission area EMA1c may also be larger than an area of the third emission area EMA3c. In another embodiment, the area of the first emission area EMA1c may be equal to or substantially equal to the area of the third emission area EMA3c.

Along the first direction DR1, a first metal line JHL1c may sequentially include a first metal pattern UR1c protruding in the second direction DR2, a second metal pattern UR2c protruding in the second direction DR2, and a third metal pattern UR3c protruding in the second direction DR2. Lengths of the first, second, and third metal patterns UR1c, UR2c, and UR3c in the second direction DR2 may be the same or substantially the same as each other.

The first metal line JHL1c may further include a first line portion LP1c connecting the first metal pattern UR1c and the second metal pattern UR2c to each other, and a second line portion LP2c connecting the second metal pattern UR2c and the third metal pattern UR3c to each other. Positions of the first line portion LP1c and the second line portion LP2c may be the same or substantially the same as each other with respect to the second direction DR2. Lengths of the first line portion LP1c and the second line portion LP2c in the first direction DR1 may be the same or substantially the same as each other.

Along the first direction DR1, a second metal line JHL2c may sequentially include a fourth metal pattern UR4c protruding in the opposite direction of the second direction DR2, a fifth metal pattern UR5c protruding in the opposite direction of the second direction DR2, and a sixth metal pattern UR6c protruding in the opposite direction of the second direction DR2. Shapes of the fourth metal pattern UR4c and the sixth metal pattern UR6c may be the same or substantially the same as each other. A shape of the fifth metal pattern UR5c may be symmetrical or substantially symmetrical to the shape of the fourth metal pattern UR4c in the first direction DR1.

The second metal line JHL2c may further include a third line portion LP3c connecting the fourth metal pattern UR4c and the fifth metal pattern UR5c to each other, and a fourth line portion LP4c connecting the fifth metal pattern UR5c and the sixth metal pattern UR6c to each other. Positions of the third line portion LP3c and the fourth line portion LP4c may be different from each other with respect to the second direction DR2. Lengths of the third line portion LP3c and the fourth line portion LP4c in the first direction DR1 may be the same or substantially the same as each other.

The first emission area EMA1c may be located between the first line portion LP1c and the third line portion LP3c. The second emission area EMA2c may be located between the second line portion LP2c and the fourth line portion LP4c. A distance between the first line portion LP1c and the third line portion LP3c may be smaller (e.g., narrower) than a distance between the second line portion LP2c and the fourth line portion LP4c.

The third emission area EMA3c may be located in the second direction DR2 from the third line portion LP3c. A third metal line JHL3c having the same or substantially the same shape as that of the first metal line JHL1c may be located in the second direction DR2 from the third emission area EMA3c. A leakage current in the second direction DR2 from the third emission area EMA3c may be blocked by the third metal line JHL3c.

The second metal pattern UR2c and the fifth metal pattern UR5c may face each other between the first emission area EMA1c and the second emission area EMA2c. In addition, the first metal pattern UR1c and the fourth metal pattern UR4c may face each other in the opposite direction of the first direction DR1 from the first emission area EMA1c. In addition, the third metal pattern UR3c and the sixth metal pattern UR6c may face each other between the second emission area EMA2c and the seventh emission area EMA7c. Positions of the metal patterns UR1c, UR2c, UR3c, UR4c, and UR5c may be arranged such that a length of the first metal line JHL1c and a length of the second metal line JHL2c are the same or substantially the same as each other. Therefore, resistance values of the metal lines JHL1c and JHL2c may be the same or substantially the same as each other, and heat may be uniformly generated in a Joule heating process.

A dummy metal line JHDLc may be located in the second direction DR2 from the pixels located at an outermost portion in the second direction DR2 from among the pixels. For example, in FIG. 11, the second pixel PXL2c and the fourth pixel PXL4c are illustrated as the pixels located at the outermost portion in the second direction DR2. An upper area UPAc located in the second direction DR2 from the second pixel PXL2c and the fourth pixel PXL4c may correspond to the non-display area NDA, and may not include any sub-pixels (or the emission areas thereof). The dummy metal line JHDLc is located in the second direction DR2 from the second pixel PXL2c and the fourth pixel PXL4c, so that a leakage current in the second direction DR2 from the emission areas EMA5c, EMA6c, EMA11c, and EMA12c may be prevented or substantially prevented. Both ends (e.g., opposite ends) of the dummy metal line JHDLc may be connected to the first metal pad JPD1 and the second metal pad JPD2, respectively, and may be supplied with a power voltage like that of the other metal lines JHL1c, JHL2c, JHL3c, and JHL4c. The dummy metal line JHDLc may have the same or substantially the same shape as the first metal line JHL1c and/or the third metal line JHL3c.

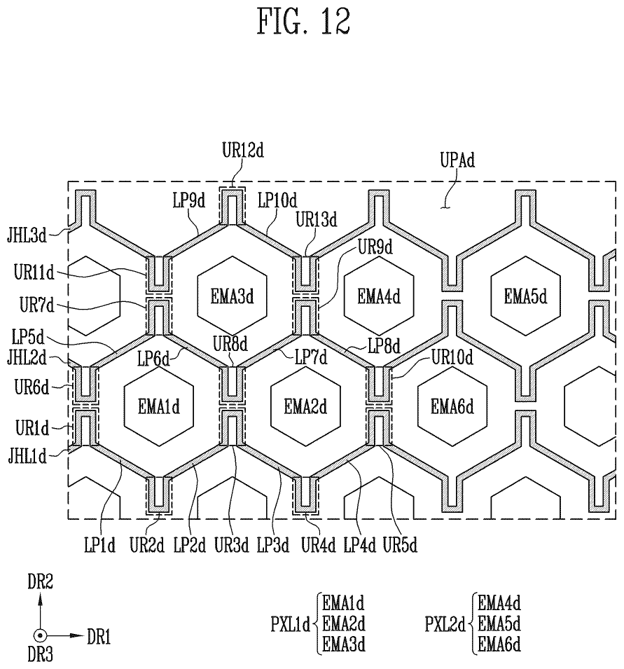

FIG. 12 is a view illustrating a metal line that is applied to another kind of pixels according to one or more embodiments.

A first pixel PXL1d may include a first sub-pixel and a second sub-pixel, which are arranged along the first direction DR1. Also, the first pixel PXL1d may include a third sub-pixel located in the second direction DR2 between the first sub-pixel and the second sub-pixel. The first sub-pixel may include a first emission area EMA1d, the second sub-pixel may include a second emission area EMA2d, and the third sub-pixel may include a third emission area EMA3d. The first to third emission areas EMA1d, EMA2d, and EMA3d may have a hexagonal shape. In another embodiment, the first to third emission areas EMA1d, EMA2d, and EMA3d may have a circular shape. The shape of the first to third emission areas EMA1d, EMA2d, and EMA3d is not limited thereto, and may be variously modified as needed or desired, such as depending on a desired product.

A second pixel PXL2d may include a fourth sub-pixel and a fifth sub-pixel, which are arranged along the first direction DR1. Also, the second pixel PXL2d may include a sixth sub-pixel located in the opposite direction of the second direction DR2 between the fourth sub-pixel and the fifth sub-pixel. The fourth sub-pixel may include a fourth emission area EMA4d, the fifth sub-pixel may include a fifth emission area EMA5d, and the sixth sub-pixel may include a sixth emission area EMA6d. The fourth to sixth emission areas EMA4d, EMA5d, and EMA6d may have a hexagonal shape. In another embodiment, the fourth to sixth emission areas EMA4d, EMA5d, and EMA6d may have a circular shape. The shape of the fourth to sixth emission areas EMA4d, EMA5d, and EMA6d is not particularly limited, and may variously modified as needed or desired, such as depending on a desired product.

Hereinafter, for convenience, the first pixel PXL1d will be mainly described in more detail. The second pixel PXL2d and the other pixels that are not shown in FIG. 12 may have the same or substantially the same configuration as that of the first pixel PXL1d, and thus, redundant description thereof may not be repeated.

Each of a plurality of metal lines JHL1d, JHL2d, and JHL3d may extend in the first direction DR1, and may not overlap with the emission areas of the sub-pixels. The plurality of metal lines JHL1d, JHL2d, and JHL3d may include metal patterns protruding in a direction intersecting or crossing the first direction DR1 between the emission areas.

The metal lines JHL1d, JHL2d, and JHL3d may include a first group of metal lines JHL1d and JHL3d and a second group of metal lines JHL2d, . . . , and the like. The first group of metal lines JHL1d and JHL3d and the second group of metal lines JHL2d, . . . may be alternately arranged along the second direction DR2. In an embodiment, the first group of metal lines JHL1d and JHL3d and the second group of metal lines JHL2d, . . . may have shapes that are symmetrical or substantially symmetrical to each other with respect to the second direction DR2.

Along the first direction DR1, a first metal line JHL1d may sequentially include a first metal pattern UR1d protruding in the second direction DR2, a second metal pattern UR2d protruding in the opposite direction of the second direction DR2, a third metal pattern UR3d protruding in the second direction DR2, a fourth metal pattern UR4d protruding in the opposite direction of the second direction DR2, and a fifth metal pattern UR5d protruding in the second direction DR2. The first emission area EMA1d may be located in the second direction DR2 from the second metal pattern UR2d. The second emission area EMA2d may be located in the second direction DR2 from the fourth metal pattern UR4d.

The first metal line JHL1d may include a first line portion LP1d connecting the first metal pattern UR1d and the second metal pattern UR2d to each other, a second line portion LP2d connecting the second metal pattern UR2d and the third metal pattern UR3d to each other, a third line portion LP3d connecting the third metal pattern UR3d and the fourth metal pattern UR4d to each other, and a fourth line portion LP4d connecting the fourth metal pattern UR4d and the fifth metal pattern UR5d to each other.

The first line portion LP1d and the third line portion LP3d may be parallel or substantially parallel to each other. For example, the first line portion LP1d and the third line portion LP3d may extend in a direction between the opposite direction of the second direction DR2 and the first direction DR1. The second line portion LP2d and the fourth line portion LP4d may be parallel or substantially parallel to each other. For example, the second line portion LP2d and the fourth line portion LP4d may extend in a direction between the second direction DR2 and the first direction DR1. Therefore, the first line portion LP1d and the second line portion LP2d may not be parallel to each other.

Along the first direction DR1, a second metal line JHL2d may sequentially include a sixth metal pattern UR6d protruding in the opposite direction of the second direction DR2, a seventh metal pattern UR7d protruding in the second direction DR2, an eighth metal pattern UR8d protruding in the opposite direction of the second direction DR2, a ninth metal pattern UR9d protruding in the second direction DR2, and a tenth metal pattern UR10d protruding in the opposite direction of the second direction DR2. The first emission area EMA1d may be located in the opposite direction of the second direction DR2 from the seventh metal pattern UR7d. The second emission area EMA2d may be located in the opposite direction of the second direction DR2 from the ninth metal pattern UR9d. The third emission area EMA3d may be located in the second direction DR2 from the eighth metal pattern UR8d. The third metal pattern UR3d and the eighth metal pattern UR8d may face each other between the first emission area EMA1d and the second emission area EMA2d.

Along the first direction DR1, a third metal line JHL3d may sequentially include an eleventh metal pattern UR11d protruding in the opposite direction of the second direction DR2, a twelfth metal pattern UR12d protruding in the second direction DR2, and a thirteenth metal pattern UR13d protruding in the opposite direction of the second direction DR2. The third emission area EMA3d may be located in the opposite direction of the second direction DR2 from the twelfth metal pattern UR12d. The eleventh metal pattern UR11d and the seventh metal pattern UR7d may face each other in the second direction DR2. The thirteenth metal pattern UR13d and the ninth metal pattern UR9d may face each other in the second direction DR2.

FIG. 12 shows that an upper area UPAd in the non-display area NDA, which is located in the second direction DR2, may not include any dummy metal line, because the third metal line JHL3d located in the display area DA may prevent or substantially prevent a leakage current in the second direction DR2 from the emission areas EMA3d, EMA4d, and EMA5d.

Lengths of the metal lines JHL1d, JHL2d, and JHL3d may be the same or substantially the same as each other. Therefore, resistance values of the metal lines JHL1d, JHL2d, and JHL3d may be the same or substantially the same as each other, and heat may be uniformly generated in a Joule heating process.

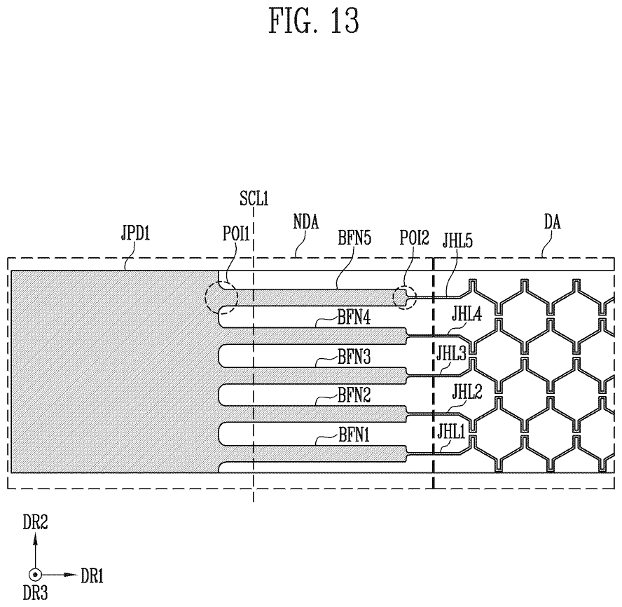

FIG. 13 is a view illustrating a connection portion of a metal pad and metal lines.

Referring to FIG. 13, portions of the first metal pad JPD1 and metal lines JHL1 to JHL5 are enlarged and illustrated at a boundary of the non-display area NDA and the display area DA.

According to one or more embodiments, the first metal pad JPD1 and the metal lines JHL1 to JHL5 may be connected to one another by connection portions BFN1 to BFN5. The connection portions BFN1 to BFN5 and the metal lines JHL1 to JHL5 may be connected to one another to correspond one-to-one to each other.

A width of each of the connection portions BFN1 to BFN5 in the second direction DR2 may be larger (e.g., wider) than a width of each of the metal lines JHL1 to JHL5 in the second direction DR2. In addition, a connection area POI1 of the first metal pad JPD1 and each of the connection portions BFN1 to BFN5 may have a curved shape. In addition, a connection area POI2 of each of the connection portions BFN1 to BFN5 and each of the corresponding metal lines JHL1 to JHL5 may have a curved shape. Because each of the connection areas POI1 and POI2 may have a curved shape, a current deflection phenomenon may be prevented or substantially prevented. If the current deflection phenomenon occurs, a spark may occur, and sublimation of the light emitting structure EMS due to unintended heat generation may be made in an area close to the display area DA.

While FIG. 3 illustrates the first metal pad JPD1, the second metal pad JPD2 may have the same or substantially the same connection structure and relationship as those of the first metal pad JPD1 described above, and thus, redundant description thereof will not be repeated.

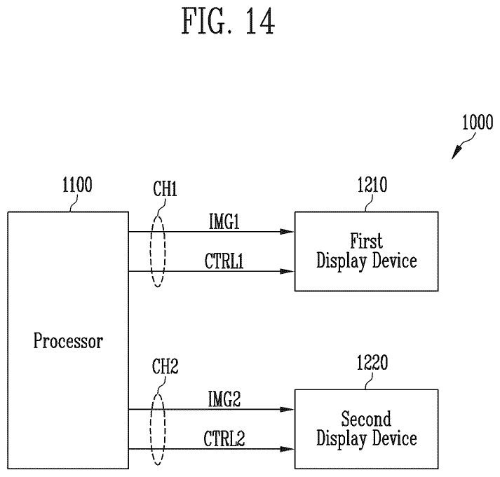

FIG. 14 is a diagram illustrating a display system according to one or more embodiments.

Referring to FIG. 14, the display system 1000 may include a processor 1100, and one or more display devices 1210 and 1220.

The processor 1100 may perform various tasks and various calculations. In one or more embodiments, the processor 1100 may include an Application Processor (AP), a Graphics Processing Unit (GPU), a microprocessor, a Central Processing Unit (CPU), and/or the like. The processor 1100 may be connected to other components of the display system 1000 through a bus system to control the components of the display system 1000.

FIG. 14 shows that the display system 1000 includes first and second display devices 1210 and 1220. The processor 1100 may be connected to the first display device 1210 through a first channel CH1, and may be connected to the second display device 1220 through a second channel CH2.

Through the first channel CH1, the processor 1210 may transmit first image data IMG1 and a first control signal CTRL1 to the first display device 1210. The first display device 1210 may display an image based on the first image data IMG1 and the first control signal CTRL1. The first display device 1210 may have the same or substantially the same configuration as that of the display device 100 described above with reference to FIG. 1. The first image data IMG1 and the first control signal CTRL1 may be provided as the image data IMG and the control signal CTRL, respectively, as shown in FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may have the same or substantially the same configuration as that of the display device 100 described above with reference to FIG. 1. The second image data IMG2 and the second control signal CTRL2 may be provided as the image data IMG and the control signal CTRL, respectively, as shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, and/or an augmented reality (AR) device.

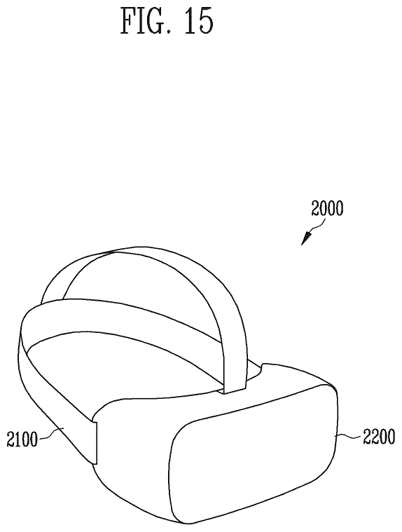

FIG. 15 is a perspective view illustrating an application example of the display system shown in FIG. 14.

Referring to FIG. 15, the display system 1000 shown in FIG. 14 may be applied to a head mounted display device 2000. The head mounted display device 2000 may be a wearable electronic device that can be worn on the head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, and may be used to fix the head mounted display device 2000 to the head of the user. The horizontal band may surround a side portion of the head of the user, and the vertical band may surround an upper portion of the head of the user. However, the present disclosure is not limited thereto. For example, the head mounting band 2100 may be implemented in the form of a glasses frame, a helmet, or the like.

The display device accommodating case 2200 may accommodate the first and second display devices 1210 and 1220 shown in FIG. 14. The display device accommodating case 2200 may further accommodate the processor 1100 shown in FIG. 14.

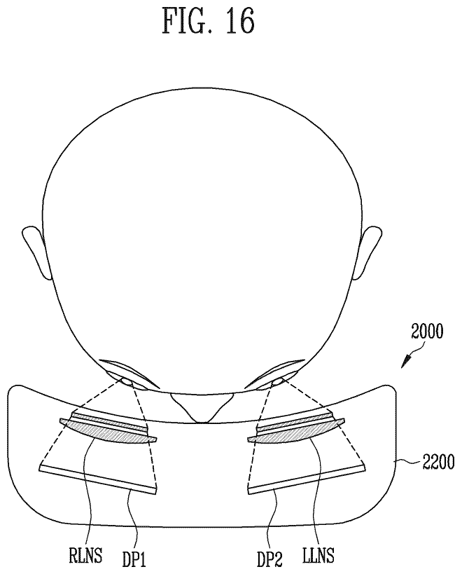

FIG. 16 is a view illustrating the head mounted display device shown in FIG. 15 that is worn by a user.

Referring to FIG. 16, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and the right eye of the user. In the display device accommodating case 2200, a left-eye lens LLNS may be disposed between the second display panel DP2 and the left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In one or more embodiments, each of the right-eye lens RLNS and the left-eye lens LLNS may include an optical lens having a pancake-shaped section. In some embodiments, each of the right-eye lens RLNS and the left-eye lens LLNS may include a multi-channel lens including sub-areas having different optical characteristics. Each display panel DP1 and DP2 may output images corresponding to the sub-areas of the multi-channel lens, respectively, and the output images may be viewed by the user while respectively passing through the corresponding sub-areas.

In the display device and the wearable device in accordance with one or more embodiments of the present disclosure, a leakage current through a common layer between adjacent pixels may be prevented or substantially prevented.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate including a non-display area and a display area;
sub-pixels in the display area; and
metal lines traversing the non-display area and the display area in a first direction,
wherein each of the metal lines extends in the first direction to not overlap with emission areas of the sub-pixels, and comprises metal patterns protruding in a direction crossing the first direction between the emission areas.

2. The display device of claim 1, wherein each of the metal patterns has a ring shape.

3. The display device of claim 2, wherein each of the metal lines is located on a pixel defining layer, and the pixel defining layer defines the emission areas of the sub-pixels in the display area.

4. The display device of claim 1, further comprising:
a first metal pad in the non-display area; and
a second metal pad in the non-display area, the second metal pad being located in the first direction from the first metal pad,
wherein the metal lines connect the first metal pad and the second metal pad to each other.

5. The display device of claim 1, wherein shapes of the metal lines are the same as each other.

6. The display device of claim 1, wherein the sub-pixels comprise a first sub-pixel, a second sub-pixel, and a third sub-pixel located along the first direction, and
wherein the metal lines comprise a first metal line, the first metal line comprising:
a first metal pattern protruding in a second direction crossing the first direction between a first emission area of the first sub-pixel and a second emission area of the second sub-pixel; and
a second metal pattern protruding in the second direction between the second emission area and a third emission area of the third sub-pixel.

7. The display device of claim 6, wherein a length of each of the first metal pattern and the second metal pattern in the second direction is longer than a length of each of the first emission area, the second emission area, and the third emission area in the second direction.

8. The display device of claim 7, wherein the first metal line further comprises:
a first line portion located in an opposite direction of the second direction from the first emission area, the first line portion being connected to the first metal pattern;
a second line portion located in the opposite direction of the second direction from the second emission area, the second line portion connecting the first metal pattern and the second metal pattern to each other; and
a third line portion located in the opposite direction of the second direction from the third emission area, the third line portion being connected to the second metal pattern.

9. The display device of claim 8, wherein the sub-pixels further comprise a fourth sub-pixel, a fifth sub-pixel, and a sixth sub-pixel located along the first direction,
wherein the metal lines further comprise a second metal line traversing between the first emission area and a fourth emission area of the fourth sub-pixel, between the second emission area and a fifth emission area of the fifth sub-pixel, and between the third emission area and a sixth emission area of the sixth sub-pixel, and
wherein a first metal line and the second metal line are spaced from each other.

10. The display device of claim 6, wherein the metal lines further comprise a dummy metal line located in the second direction from outermost sub-pixels in the second direction from among the sub-pixels.

11. The display device of claim 1, wherein the metal lines comprise:
a first group of metal lines comprising metal patterns protruding in a second direction crossing the first direction; and
a second group of metal lines comprising metal patterns protruding in an opposite direction of the second direction, and
wherein the first group of metal lines and the second group of metal lines are alternately located along the second direction.

12. The display device of claim 11, wherein the first group of metal lines and the second group of metal lines have shapes that are symmetrical to each other with respect to the second direction.

13. The display device of claim 1, wherein the sub-pixels comprise a first sub-pixel and a second sub-pixel located along the first direction,
wherein the metal lines comprise a first metal line sequentially comprising along the first direction:
a first metal pattern protruding in a second direction crossing the first direction;
a second metal pattern protruding in an opposite direction of the second direction;
a third metal pattern protruding in the second direction;
a fourth metal pattern protruding in the opposite direction of the second direction; and
a fifth metal pattern protruding in the second direction,
wherein a first emission area of the first sub-pixel is located in the second direction from the second metal pattern, and
wherein a second emission area of the second sub-pixel is located in the second direction from the fourth metal pattern.

14. The display device of claim 13, wherein the first metal line further comprises:
a first line portion connecting the first metal pattern and the second metal pattern to each other;
a second line portion connecting the second metal pattern and the third metal pattern to each other;
a third line portion connecting the third metal pattern and the fourth metal pattern to each other; and
a fourth line portion connecting the fourth metal pattern and the fifth metal pattern to each other, and
wherein:
the first line portion and the third line portion are parallel to each other;
the second line portion and the fourth line portion are parallel to each other; and
the first line portion and the second line portion are not parallel to each other.

15. The display device of claim 14, wherein the sub-pixels further comprise a third sub-pixel,
wherein the metal lines further comprise a second metal line sequentially comprising along the first direction:
a sixth metal pattern protruding in the opposite direction of the second direction;
a seventh metal pattern protruding in the second direction;
an eighth metal pattern protruding in the opposite direction of the second direction;
a ninth metal pattern protruding in the second direction; and
a tenth metal pattern protruding in the opposite direction of the second direction,
wherein the first emission area is located in the opposite direction of the second direction from the seventh metal pattern,
wherein the second emission area is located in the opposite direction of the second direction from the ninth metal pattern, and
wherein a third emission area of the third sub-pixel is located in the second direction from the eighth metal pattern.

16. The display device of claim 15, wherein the third metal pattern and the eighth metal pattern face each other between the first emission area and the second emission area.

17. The display device of claim 16, wherein the metal lines further comprise a third metal line sequentially comprising along the first direction:
an eleventh metal pattern protruding in the opposite direction of the second direction;
a twelfth metal pattern protruding in the second direction; and
a thirteenth metal pattern protruding in the opposite direction of the second direction,
wherein the third emission area is located in the opposite direction of the second direction from the twelfth metal pattern,
wherein the eleventh metal pattern and the seventh metal pattern face each other in the second direction, and
wherein the thirteenth metal pattern and the ninth metal pattern face each other in the second direction.

18. The display device of claim 1, wherein the metal lines comprise:
a first metal line sequentially comprising along the first direction:
a first metal pattern protruding in a second direction crossing the first direction;
a second metal pattern protruding in the second direction; and
a third metal pattern protruding in the second direction; and
a second metal line sequentially comprising along the first direction:
a fourth metal pattern protruding in an opposite direction of the second direction;
a fifth metal pattern protruding in the opposite direction of the second direction; and
a sixth metal pattern protruding in the opposite direction of the second direction,
wherein the first metal line further comprises:
a first line portion connecting the first metal pattern and the second metal pattern to each other; and
a second line portion connecting the second metal pattern and the third metal pattern to each other,
wherein the second metal line further comprises:
a third line portion connecting the fourth metal pattern and the fifth metal pattern to each other; and
a fourth line portion connecting the fifth metal pattern and the sixth metal pattern to each other,
wherein positions of the first line portion and the second line portion are the same as each other with respect to the second direction, and
wherein positions of the third line portion and the fourth line portion are different from each other with respect to the second direction.

19. The display device of claim 18, wherein the sub-pixels comprise:
a first sub-pixel comprising a first emission area;
a second sub-pixel located in the first direction from the first sub-pixel, and comprising a second emission area; and
a third sub-pixel located in the second direction from the first sub-pixel, and comprising a third emission area,
wherein a length of the second emission area in the second direction is longer than a length of each of the first emission area and the third emission area in the second direction,
wherein the first emission area is located between the first line portion and the third line portion,
wherein the second emission area is located between the second line portion and the fourth line portion, and
wherein the third emission area is located in the second direction from the third line portion.

20. The display device of claim 19, wherein the second metal pattern and the fifth metal pattern face each other between the first emission area and the second emission area.

21. A wearable device comprising:
a first display panel; and
a second display panel,
wherein each of the first display panel and the second display panel comprises:
a substrate including a non-display area and a display area;
sub-pixels in the display area; and
metal lines traversing the non-display area and the display area in a first direction, and
wherein each of the metal lines extends in the first direction to not overlap with emission areas of the sub-pixels, and comprises metal patterns protruding in a direction crossing the first direction between the emission areas.
